(19) United States
(12) Patent Application Publication
(10) Pub. No.: US 2026/0033062 A1
(43) Pub. Date: Jan. 29, 2026

(54) DISPLAY DEVICE

(71) Applicant: LG DISPLAY CO., LTD., SEOUL (KR)

(72) Inventors: Seongsoo Cho, Paju-si (KR); WooSung Kim, Paju-si (KR); Hyunseok Na, Paju-si (KR); SangHak Shin, Paju-si (KR)

(21) Appl. No.: 19/277,544

(22) Filed: Jul. 23, 2025

(30) Foreign Application Priority Data
Jul. 23, 2024 (KR) 10-2024-0097120

(51) Int. Cl. H10H 29/37; H10H 29/49; H10H 29/855

(52) U.S. Cl. CPC H10H 29/37; H10H 29/49; H10H 29/8552

(57) ABSTRACT

A display device is provided, the display device including: a substrate including a display area and a non-display area; a pixel driving circuit disposed in the display area on the substrate; a bank disposed on the pixel driving circuit; a light emitting element disposed on the bank; an optical layer covering side surfaces of the bank and the light emitting element; a black matrix disposed on the optical layer; and a first barrier layer disposed on an inclined surface of a first contact hole in the optical layer.

### CROSS-REFERENCE TO RELATED APPLICATION

Pursuant to 35 U.S.C. § 119(a), this application claims the benefit of an earlier filing date and right of priority of Korean Patent Application No. 10-2024-0097120, filed in the Republic of Korea on Jul. 23, 2024, the disclosure of which is hereby incorporated by reference in its entirety.

### TECHNICAL FIELD

The present disclosure relates to a display device.

### BACKGROUND

With the development of information technology, many related technologies have been developed in the field of display devices for visually displaying information, such as text, images, video, or graphical data. A display device is an output device that converts electrical signals into visible light patterns, typically using an array of pixels composed of sub-pixels.

### SUMMARY

Display devices can be applied to various electronic devices such as televisions (TVs), mobile phones, laptops, and tablets. Examples of display devices include organic light emitting displays (OLEDs) that are self-luminous, and liquid crystal displays (LCDs) that include a separate light source. Recently, display devices that include light emitting diodes (LEDs) have attracted attention as next-generation display devices. Since the light emitting diodes can be made of inorganic materials rather than organic materials, they may light up faster than liquid crystal displays and organic light emitting diode displays, have excellent light emitting efficiency, and may display high-brightness images.

In one example of a display device including a light emitting element (ED), e.g., a light emitting diode (LED) or a micro light emitting diode (micro LED), a plurality of protective layers and insulating layers are formed to protect a pixel driving circuit and the light emitting element, and a plurality of wires and/or electrodes are disposed between the plurality of protective layers and insulating layers. In this case, a plurality of contact holes is formed to electrically connect the plurality of wires and/or electrodes, but an area where the plurality of contact holes is formed may be damaged by moisture and/or gas contained in the adjacent protective layers and insulating layers. Furthermore, when the area where the plurality of contact holes is formed is damaged, the plurality of wires and/or electrodes may also be damaged.

Accordingly, some aspects of the present disclosure aim to provide a display device that prevents a region where a contact hole is formed from being damaged by moisture and/or gas in an insulating layer provided near the region, in order to solve the above-mentioned problem. Furthermore, by preventing the region where the contact hole is formed from being damaged, it is possible to prevent a plurality of signal lines, connection lines, and electrodes provided in the region where the contact hole is formed from being damaged.

According to one aspect of the present disclosure, a display device is provided, the display device including: a substrate including a display area and a non-display area; a pixel driving circuit disposed in the display area on the substrate; a bank disposed on the pixel driving circuit; a light emitting element disposed on the bank; an optical layer covering side surfaces of the bank and the light emitting element; a black matrix disposed on the optical layer; and a first barrier layer disposed on an inclined surface of a first contact hole in the optical layer.

The aspects of this disclosure are not limited to the aspects mentioned above, and other aspects not mentioned will be clearly understood by those of ordinary skill in the art from the description below.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is an exploded perspective view of a display device according to an example of the present disclosure.

FIG. 2 is a plan view of a display device according to an example of the present disclosure.

FIG. 3 is an enlarged view of a display device according to an example of the present disclosure.

FIG. 4 is a diagram showing a circuit structure according to an example of the present disclosure.

FIG. 5 is a plan view of a display panel according to an example of the present disclosure.

FIG. 6 is a plan view of a display panel according to an example of the present disclosure.

FIG. 7 is a plan view of a display panel according to an example of the present disclosure.

FIG. 8 is a cross-sectional view of a display panel according to an example of the present disclosure.

FIG. 9 is a cross-sectional view of a display panel according to an example of the present disclosure.

FIG. 10 is a process cross-sectional view illustrating a transfer process of a light emitting element according to an example of the present disclosure.

FIG. 11 is a cross-sectional view of a display panel according to an example of the present disclosure.

FIG. 12 is a cross-sectional view of a display panel according to an example of the present disclosure, and is an enlarged view of area A of FIG. 11.

FIG. 13 is a cross-sectional view of a display panel according to an example of the present disclosure.

FIG. 14 is a cross-sectional view of a display panel according to an example of the present disclosure, and is an enlarged view of area A of FIG. 13.

FIG. 15 is a cross-sectional view of a display panel according to an example of the present disclosure.

FIG. 16 is a cross-sectional view of a display panel according to an example of the present disclosure, and is an enlarged view of area A of FIG. 15.

FIGS. 17-20 are drawings showing devices to which display devices according to examples of the present disclosure are applied.

### DETAILED DESCRIPTION

The advantages and features of the present disclosure and methods for accomplishing the same will be more clearly understood from the examples described below with reference to the accompanying drawings. The present disclosure may, however, be embodied in different forms and should not be construed as limited to the following examples set forth herein. Rather, the following examples are provided so that this disclosure will be thorough and complete and will fully convey the scope of the present disclosure to those of ordinary skill in the art.

A shape, a size, a ratio, an angle, and a number disclosed in the accompanying drawings for describing the following examples of the present disclosure are merely examples and, thus, the present disclosure is not limited to the following examples. Unless stated otherwise, like reference numerals refer to like elements throughout the specification. In the following description, when the detailed description of the relevant known function or configuration is determined to unnecessarily obscure an important point of the present disclosure, the detailed description will be omitted. In a case where ‘comprise’, ‘have’ and ‘include’ described in the present disclosure are used, another portion may be added unless ‘only˜’ is used. The terms of a singular form may include plural forms unless referred to the contrary.

In interpreting components, even if there is no explicit description, it is interpreted to include the scope of error.

In describing a position relationship, for example, when the position relationship is described as ‘upon˜’, ‘above˜’, ‘below˜’ and ‘next to˜’, one or more portions may be disposed between two other portions unless ‘just’ or ‘direct’ is used.

In describing a temporal precedence relationship, for example, when the temporal precedence relationship is described as ‘˜after’, ‘˜next to’, ‘˜before’, etc., it may also include cases where it is not continuous unless ‘right away’ or ‘directly’ is used.

First, second, etc. are used to describe various components, but these components are not limited by these terms. These terms are used only to distinguish one component from another. Therefore, a first component mentioned below may be a second component within the technical idea of the present disclosure.

Hereinafter, various examples of the present disclosure will be described in detail with reference to the accompanying drawings.

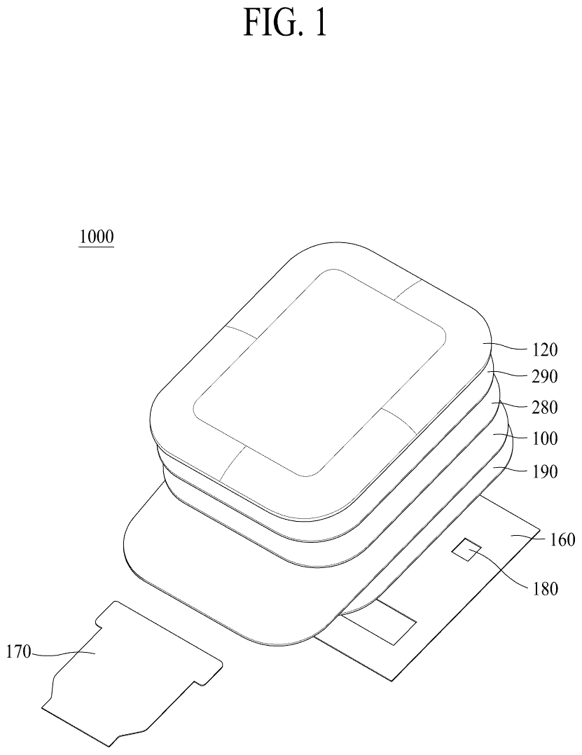

FIG. 1 is a perspective view showing a display device (1000) according to an example of the present disclosure.

Referring to FIG. 1, the display device (1000) according to an example of the present disclosure may include a display panel (100), a polarizing layer (280), an adhesive layer (290), a cover member (120), a support substrate (190), a flexible circuit board (170), and a printed circuit board (160).

The display panel (100) may implement information, e.g., text, images, and/or video provided to the user.

The polarizing layer (280) may be disposed on the display panel (100). The polarizing layer (280) may prevent or reduce light generated from an external light source from entering the display panel (100) and affecting light emitting elements, etc.

The adhesive layer (290) may attach the cover member (120) to the display panel (100). The adhesive layer (290) may be disposed between the polarizing layer (280) and the cover member (120) to attach the cover member (120) to the polarizing layer (280). The adhesive layer (290) may include an optically clear adhesive (OCA), an optically clear resin (OCR), a pressure sensitive adhesive (PSA), or the like, but the examples of the present disclosure are not limited thereto.

The cover member (120) may be disposed on the polarizing layer (280). The cover member (120) may be disposed on the adhesive layer (290). The cover member (120) may be a member for protecting the display panel (100). The cover member (120) may be made of a transparent material.

A support substrate (190) may be disposed between the display panel (100) and the printed circuit board (160). The support substrate (190) may reinforce the rigidity of the display panel (100). The support substrate (190) may be a back plate, but the examples of the present disclosure are not limited thereto.

The flexible circuit board (170) and the printed circuit board (160) may be disposed at the bottom of the display panel (100). The flexible circuit board (170) and the printed circuit board (160) may be arranged along at least one edge of the display panel (100), but the examples of the present disclosure are not limited thereto. One side of the flexible circuit board (170) may be attached to the display panel (100), and the other side may be attached to the printed circuit board (160), but the examples of the present disclosure are not limited thereto. The flexible circuit board (170) may be a flexible film, but the examples of the present disclosure are not limited thereto.

The printed circuit board (160) may include at least one hole (180), but the examples of the present disclosure are not limited thereto. An internal component that detects ambient light or temperature, etc., which may be provided to a plurality of sensors, may be disposed in an area corresponding to the hole (180). For example, the internal component may include an ambient light sensor (ALS) or a temperature sensor, but the examples of the present disclosure are not limited thereto. For example, the hole (180) may be a transmission hole, but the examples of the present disclosure are not limited thereto.

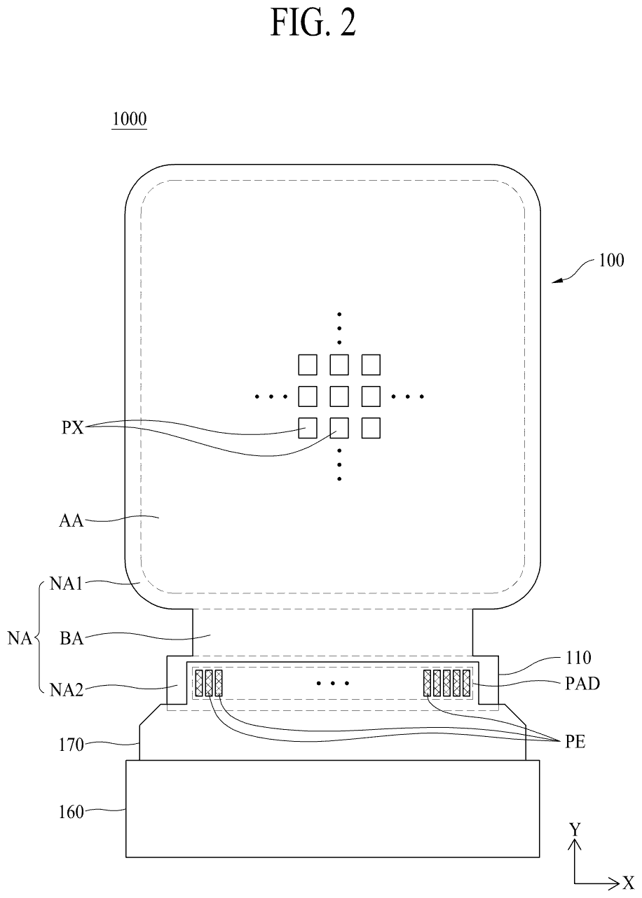

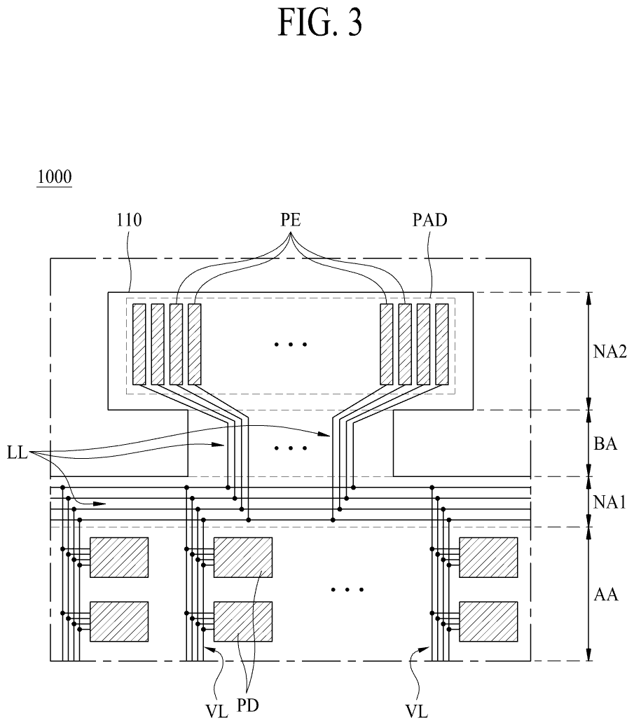

FIG. 2 is a plan view of the display device (1000) according to an example of the present disclosure, and FIG. 3 is an enlarged view of the display device (1000) according to an example of the present disclosure.

Referring to FIGS. 2 and 3, the display device (1000) may include a display panel (100), a flexible circuit board (170), and a printed circuit board (160).

The display panel (100) may include a substrate (110). The substrate (110) may be a member that supports other components of the display device (1000). The substrate (110) may be made of an insulating material. For example, the substrate (110) may be made of glass or resin. In addition, the substrate (110) may be made of a material having flexibility. For example, the substrate (110) may be made of a plastic material having flexibility, such as polyimide (PI). However, the examples of the present disclosure are not limited thereto.

The display panel (100) may include a display area (AA) and a non-display area (NA). The display area (AA) and the non-display area (NA) are not limited to the substrate (110) but may be implemented throughout the display panel (100).

The display area (AA) may be an area where an image is displayed. The display area (AA) may include a plurality of pixels (PX). Each of the plurality of pixels (PX) may be composed of a plurality of subpixels. A plurality of light emitting elements may be arranged in each of the plurality of subpixels. The plurality of light emitting elements may be configured differently depending on the type of the display device (1000). For example, if the display device (1000) is an inorganic light emitting display device, the light emitting element may be an LED (Light-Emitting Diode), a micro-LED (Micro Light-Emitting Diode), or a mini-LED (Mini Light-Emitting Diode), but the examples of the present disclosure are not limited thereto.

The display area (AA) may be configured in various shapes depending on the design of the display device (1000). For example, the display area (AA) may be configured in a rectangular shape with four corners formed in a round shape, but the examples of the present disclosure are not limited thereto. For another example, the display area (AA) may be configured in a rectangular shape with four corners formed in a right-angle shape, a circular shape, etc., but the examples of the present disclosure are not limited thereto.

Referring to FIG. 3, a plurality of pixel driving circuits (PDs) may be disposed in the display area (AA). The plurality of pixel driving circuits (PDs) may be circuits for driving light emitting elements of a plurality of subpixels. Each of the plurality of pixel driving circuits (PDs) includes a plurality of transistors including a driving transistor and a storage capacitor, and may supply a control signal, power, and a driving current to the light emitting elements of the plurality of subpixels to control light emitting operations of the plurality of light emitting elements. For example, the plurality of pixel driving circuits (PDs) may include a power wiring and a signal wiring for controlling light emitting on/off and/or light emitting time of the light emitting elements. For example, the plurality of pixel driving circuits (PDs) may be display driving circuits manufactured using a MOSFET (Metal-Oxide-Silicon Field Effect Transistor) manufacturing process on a semiconductor substrate, but the examples of the present disclosure are not limited thereto.

The non-display area (NA) may be an area where an image is not displayed. Various wiring and circuits for driving a plurality of pixels (PX) of the display area (AA) may be disposed in the non-display area (NA). For example, various wiring and driving circuits may be mounted in the non-display area (NA), and a pad portion (PAD) to which an integrated circuit and a printed circuit are connected may be disposed, but the examples of the present disclosure are not limited thereto.

For example, the driving circuit may be a data driving circuit and/or a gate driving circuit, but the examples of the present disclosure are not limited thereto. Wires supplied with control signals for controlling the driving circuits may be disposed in the non-display area (NA). For example, the control signals may include various timing signals including a clock signal, an input data enable signal, and synchronization signals, but the examples of the present disclosure are not limited thereto. The control signal may be received through the pad portion (PAD). For example, a plurality of link lines (LL) for transmitting signals may be disposed in the non-display area (NA). For example, driving components such as a flexible circuit board (170) and a printed circuit board (160) may be connected to the pad portion (PAD).

According to the present disclosure, the non-display area (NA) may include a first non-display area (NA1), a bending area (BA), and a second non-display area (NA2). For example, the first non-display area (NA1) may be an area surrounding at least a portion of the display area (AA). The bending area (BA) may be an area extending from at least one of a plurality of sides of the first non-display area (NA1) and may be a bendable area. The second non-display area (NA2) may be an area extending from the bending area (BA) and may have a pad portion (PAD) disposed thereon. For example, the bending area (BA) may be in a bent state, and the remaining area of the substrate (110) excluding the bending area (BA) may be in a flat state. In this case, as the bending area (BA) is bent, the second non-display area (NA2) may be disposed on the back surface of the display area (AA). However, the examples of the present disclosure are not limited thereto.

The plurality of link lines (LL) may be disposed in the non-display area (NA). The plurality of link lines (LL) may be wires that transmit various signals from one or more flexible circuit boards (or flexible films) (170) and printed circuit boards (160) to the display area (AA). The plurality of link lines (LL) may extend from a plurality of pad electrodes (PE) of the second non-display area (NA2) toward the bending area (BA) and the first non-display area (NA1), and may be electrically connected to a plurality of driving wires (VL) of the display area (AA). A plurality of pixel driving circuits (PD) may be driven by receiving signals from one or more flexible circuit boards (or flexible films) (170) and printed circuit boards (160) through the driving wires (VL) of the display area (AA) and the link lines (LL) of the non-display area (NA).

For example, the plurality of driving wires (VL) may be wires for transmitting signals output from the flexible circuit board (or flexible film) (170) and the printed circuit board (160) together with the plurality of link lines (LL) to the plurality of pixel driving circuits (PD). The plurality of driving wires (VL) may be arranged in the display area (AA) and may be electrically connected to each of the plurality of pixel driving circuits (PD). The plurality of driving wires (VL) may extend from the display area (AA) toward the non-display area (NA) and may be electrically connected to the plurality of link lines (LL). Therefore, the signals output from the flexible circuit board (or flexible film) (170) and the printed circuit board (160) may be transmitted to each of the plurality of pixel driving circuits (PD) through the plurality of link lines (LL) and the plurality of driving wires (VL).

As the bending area (BA) is bent, a portion of the plurality of link lines (LL) may also be bent together. Stress is concentrated on a portion of the bent link lines (LL), and thus cracks may occur in the link lines (LL). Accordingly, the plurality of link lines (LL) may be formed of a conductive material having excellent ductility to reduce cracks when the bending area (BA) is bent. For example, the plurality of link lines (LL) may be formed of a conductive material having excellent ductility, such as gold (Au), silver (Ag), aluminum (Al), or the like, but the examples of the present disclosure are not limited thereto. In addition, the plurality of link lines (LL) may be formed of one of various conductive materials used in the display area (AA). For example, the plurality of link lines (LL) may be composed of molybdenum (Mo), chromium (Cr), titanium (Ti), nickel (Ni), neodymium (Nd), copper (Cu), and an alloy of silver (Ag) and magnesium (Mg), or an alloy thereof, but the examples of the present disclosure are not limited thereto. The plurality of link lines (LL) may be composed of a multilayer structure including various conductive materials. For example, the plurality of link lines (LL) may be composed of a triple layer structure of titanium (Ti)/aluminum (Al)/titanium (Ti), but the examples of the present disclosure are not limited thereto.

The plurality of link lines (LL) may be configured in various shapes to reduce stress. At least a portion of the plurality of link lines (LL) disposed on the bending area (BA) may extend in the same direction as the extension direction of the bending area (BA), or may extend in a direction different from the extension direction of the bending area (BA) to reduce stress. For example, when the bending area (BA) extends in one direction from the first non-display area (NA1) toward the second non-display area (NA2), at least a portion of the link lines (LL) disposed on the bending area (BA) may extend in a direction oblique to the one direction. As another example, at least a portion of the plurality of link lines (LL) may be configured in patterns of various shapes. For example, at least a portion of the plurality of link lines (LL) disposed on the bending area (BA) may have a shape in which conductive patterns having at least one shape from among a diamond shape, a rhombus shape, a trapezoidal wave shape, a triangular wave shape, a sawtooth wave shape, a sine wave shape, a circular shape, and an omega (Q) shape are repeatedly arranged, but the examples of the present disclosure are not limited thereto. Accordingly, in order to minimize stress concentrated on the plurality of link lines (LL) and cracks resulting therefrom, the shapes of the plurality of link lines (LL) may be formed in various shapes including the above-described shapes, but the examples of the present disclosure are not limited thereto.

According to the present disclosure, the width of the second non-display area (NA2) in which a plurality of pad electrodes (PE) is arranged may be wider than the width of the bending area (BA) in which only the plurality of link lines (LL) is arranged. In addition, the width of the display area (AA) in which a plurality of subpixels is arranged may be wider than the width of the bending area (BA) in which only the plurality of link lines (LL) is arranged. Although the width of the bending area (BA) is illustrated as being narrower than the widths of other areas of the substrate (110) in the drawing, the shape of the substrate (110) including the bending area (BA) is exemplary, but the examples of the present disclosure are not limited thereto.

The pad portion (PAD) including a plurality of pad electrodes (PE) may be arranged in the second non-display area (NA2). A driving component including one or more flexible circuit boards (or flexible films) (170) and a printed circuit board (160) may be attached or bonded to the pad portion (PAD). The plurality of pad electrodes (PE) of the pad portion (PAD) are electrically connected to one or more flexible circuit boards (or flexible films) (170) and may transmit various signals (or power) received from the printed circuit boards (160) and the flexible circuit boards (or flexible films) (170) to a plurality of pixel driving circuits (PD) of the display area (AA).

The flexible circuit board (or flexible film) (170) may be a film in which various components are disposed on a flexible base film. For example, a driving IC such as a gate driver IC or a data driver IC may be disposed on the flexible circuit board (or flexible film) (170), but the examples of the present disclosure are not limited thereto. The driving IC may be a component that processes data and driving signals for displaying an image. The driving IC may be arranged in a manner such as a Chip-On-Glass (COG), a Chip-On-Film (COF), or a Tape-Carrier-Package (TCP) depending on the mounting method, but the examples of the present disclosure are not limited thereto. The flexible circuit board (or flexible film) (170) may be attached or bonded on a plurality of pad electrodes (PE) through a conductive adhesive layer, but the examples of the present disclosure are not limited thereto.

The printed circuit board (160) is electrically connected to one or more flexible circuit boards (or flexible films) (170) and may be a component that supplies signals to the driving IC. The printed circuit board (160) may be disposed on one side of the flexible circuit board (or flexible film) (170) and may be electrically connected to the flexible circuit board (or flexible film) (170). Various components for supplying various signals to the driving IC may be disposed on the printed circuit board (160). For example, various components such as a timing controller, a power supply, a memory, or a processor may be disposed on the printed circuit board (160). For example, the printed circuit board (160) may include a power management integrated circuit (PMIC), but the examples of the present disclosure are not limited thereto.

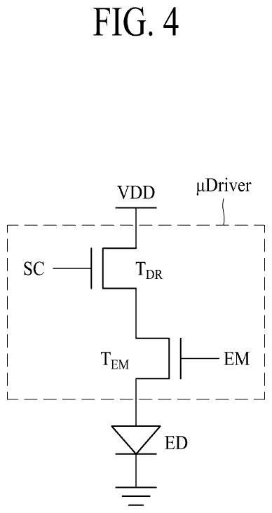

FIG. 4 is a diagram showing a circuit structure according to an example of the present disclosure.

In FIG. 4, one light emitting element (ED) is connected to one micro driver (μDriver), but the present disclosure is not limited thereto. For example, eight light emitting elements (ED) may be connected to one micro driver (μDriver). In another example, 16 light emitting elements (ED) may be connected to one micro driver (μDriver), or 32 light emitting elements (ED) or 64 light emitting elements (ED) may be connected to one micro driver (μDriver) at the same time. The light emitting elements (ED) may be micro light emitting elements (μLED).

A single micro-driver (μDriver) may include a driving transistor (TDR) and a light emitting transistor (TEM), but the examples of the present disclosure are not limited thereto.

For example, a high potential power voltage (VDD) may be applied to a first electrode of the driving transistor (TDR), and a first electrode of the light-emitting transistor (TEM) may be connected to a second electrode of the driving transistor (TDR). A scan signal (SC) may be applied to a gate electrode of the driving transistor (TDR). The scan signal (SC) applied to the gate electrode of the driving transistor (TDR) may be a direct current (DC) power source, and a fixed reference voltage (Vref) may be applied for each frame. However, the examples of the present disclosure are not limited thereto.

A second electrode of the driving transistor (TDR) may be connected to a first electrode of the light emitting transistor (TEM), a second electrode of the light-emitting transistor (TEM) may be connected to a light-emitting element (ED), and a light emission signal (EM) may be applied to a gate electrode of the light-emitting transistor (TEM). The light emission signal (EM) applied to the gate electrode of the light-emitting transistor (TEM) may be a pulse width modulation (PWM) signal that varies in each frame. However, the examples of the present disclosure are not limited thereto.

The first electrode of the light emitting element (ED) is a light emitting transistor (TEM) may be connected to the second electrode of the light emitting element (ED), and the second electrode of the light emitting element (ED) may be connected to ground. For example, the first electrode of the light emitting element (ED) may be an anode electrode, and the second electrode of the light emitting element (ED) may be a cathode electrode, but the examples of the present disclosure are not limited thereto.

Driving transistor (TDR) and light emitting transistors (TEM) may be either an n-type or a p-type transistor, respectively.

In the micro driver (μDriver), the driving transistor (T_{DR}) may be turned on by a scan signal (SC) applied from the timing controller (T-CON), and the light emitting transistor (T_{EM}) may be turned on by the light emission signal (EM). Accordingly, a driving current may be supplied to the light-emitting element (ED) through the driving transistor (T_{DR}) and the light-emitting transistor (T_{EM}), by the high potential power voltage (VDD) applied to the first electrode of the driving transistor (T_{DR}), so that the light emitting element (ED) may emit light.

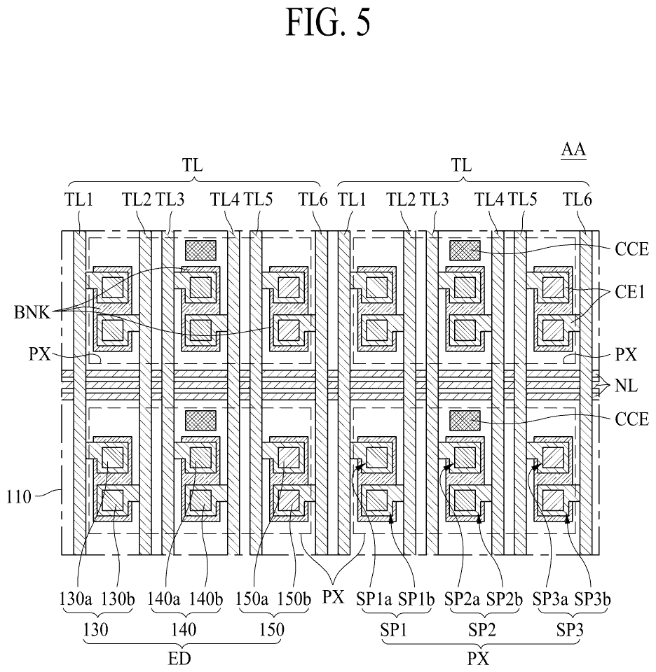

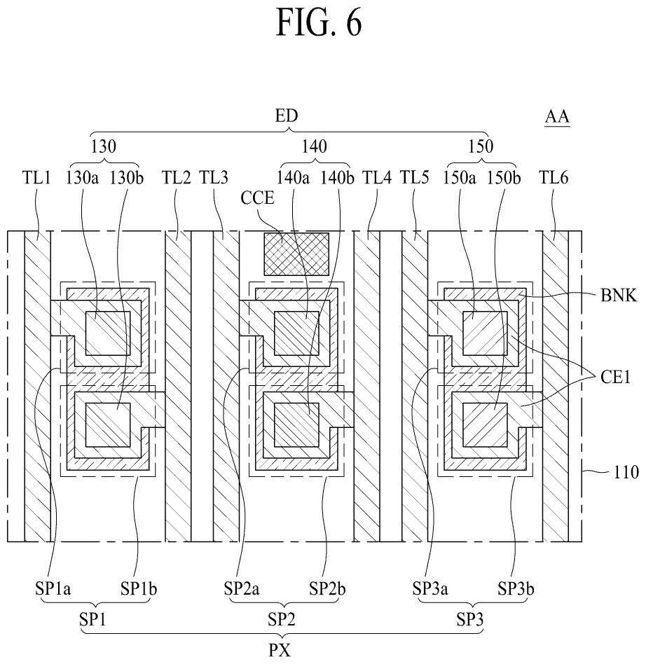

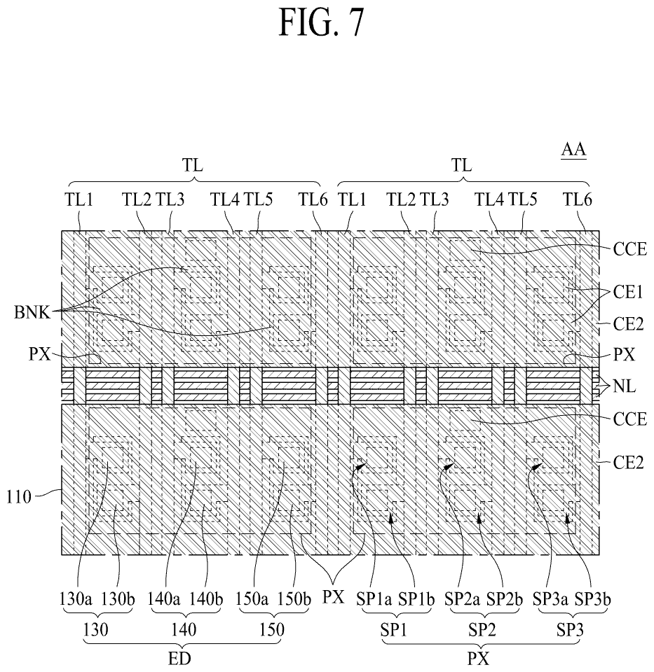

FIGS. 5-7 are plan views of the display panel (100) according to examples of the present disclosure. For example, FIG. 5 is an enlarged plan view of the display area (AA) including a plurality of pixels (PX). For example, FIG. 6 is an enlarged plan view of the display area (AA) including one pixel (PX). For example, FIG. 7 is an enlarged plan view of the display area (AA) including a plurality of pixels (PX). FIGS. 5 and 6 illustrate a plurality of signal lines (TL), a plurality of communication lines (NL), a plurality of first electrodes (CE1), a plurality of banks (BNK), and a plurality of light emitting elements (ED), but the examples of the present disclosure are not limited thereto. FIG. 7 is an enlarged plan view of FIG. 5 in which a plurality of second electrodes (CE2) are additionally arranged, and for convenience, an area overlapping with the second electrodes (CE2) is indicated with a dotted line.

Referring to FIGS. 5-7, a plurality of pixels (PX) composed of a plurality of subpixels (SP) may be arranged in a display area (AA). Each of the plurality of subpixels (SP) includes a light emitting element (ED) and may independently emit light. The plurality of subpixels (SP) may be arranged in a matrix form, forming a plurality of rows and a plurality of columns, but the examples of the present disclosure are not limited thereto.

The plurality of subpixels (SP) may include a first subpixel (SP1), a second subpixel (SP2), and a third subpixel (SP3). For example, one of the first subpixel (SP1), the second subpixel (SP2), and the third subpixel (SP3) may be a red subpixel, another may be a green subpixel, and the rest may be blue subpixels. The types of the plurality of subpixels (SP) are exemplary, and the examples of the present disclosure are not limited thereto.

Each of the plurality of pixels (PX) may include one or more first subpixels (SP1), one or more second subpixels (SP2), and one or more third subpixels (SP3). For example, one pixel (PX) may include a pair of first subpixels (SP1), a pair of second subpixels (SP2), and a pair of third subpixels (SP3). A pair of first subpixels (SP1) may be composed of a 1-1 subpixel (SP1a) and a 1-2 subpixel (SP1b). A pair of second subpixels (SP2) may be composed of a 2-1 subpixel (SP2a) and a 2-2 subpixel (SP2b). A pair of third subpixels (SP3) may be composed of a 3-1 subpixel (SP3a) and a 3-2 subpixel (SP3b). For example, one pixel (PX) may include a 1-1 subpixel (SP1a) and a 1-2 subpixel (SP1b), a 2-1 subpixel (SP2a) and a 2-2 subpixel (SP2b), and a 3-1 subpixel (SP3a) and a 3-2 subpixel (SP3b), but the examples of the present disclosure are not limited thereto.

The plurality of subpixels (SP) forming one pixel (PX) may be arranged in various ways. For example, in one pixel (PX), a pair of first subpixels (SP1) may be arranged in the same column, a pair of second subpixels (SP2) may be arranged in the same column, and a pair of third subpixels (SP3) may be arranged in the same column. The first subpixel (SP1), the second subpixel (SP2), and the third subpixel (SP3) may be arranged in the same row. The number and arrangement of the plurality of subpixels (SP) forming one pixel (PX) are exemplary, but the examples of the present disclosure are not limited thereto.

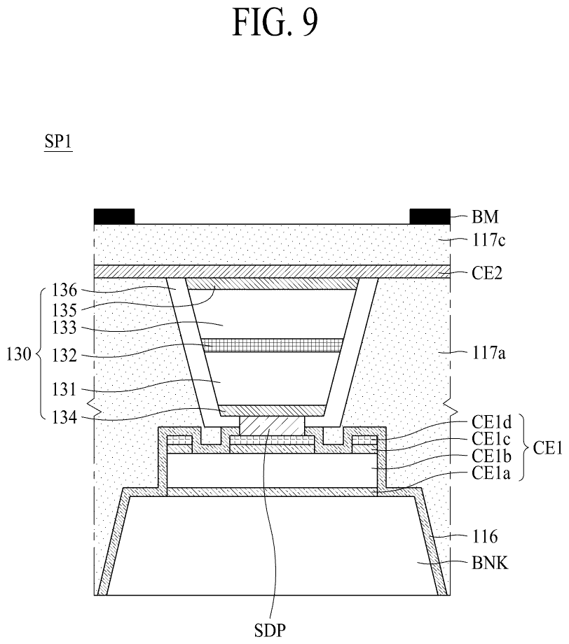

The plurality of signal lines (TL) may be disposed in an area between a plurality of subpixels (SP). The plurality of signal lines (TL) may extend in a column direction between the plurality of subpixels (SP). The plurality of signal lines (TL) may be wires that transmit an anode voltage from a pixel driving circuit (PD of FIG. 3) to the plurality of subpixels (SP). For example, the plurality of signal lines (TL) may be electrically connected to the plurality of pixel driving circuits (PD of FIG. 3) and first electrodes (CE1) of the plurality of subpixels (SP). The anode voltage output from the pixel driving circuit (PD of FIG. 3) may be transmitted to the first electrodes (CE1) of the plurality of subpixels (SP) through the plurality of signal lines (TL). For example, the first electrode (CE1) may be an electrode that is electrically connected to an anode electrode (134 of FIG. 9) of a light emitting element (ED). Accordingly, the anode voltage from the signal line (TL) may be transmitted to the anode electrode (134 in FIG. 9) of the light emitting element (ED) through the first electrode (CE1).

Accordingly, instead of forming a plurality of transistors and storage capacitors in each of a plurality of subpixels (SP), the structure of the display device (1000) may be simplified by using a pixel driving circuit (PD of FIG. 3) in which a plurality of pixel circuits is integrated. In addition, since the circuits arranged in each of a plurality of subpixels are integrated in one pixel driving circuit (PD of FIG. 3), high-efficiency, low-power driving may be possible.

The plurality of signal lines (TL) may include a first signal line (TL1), a second signal line (TL2), a third signal line (TL3), a fourth signal line (TL4), a fifth signal line (TL5), and a sixth signal line (TL6). Each of the first signal line (TL1) and the second signal line (TL2) may be electrically connected to a respective one of a pair of first subpixels (SP1). Each of the third signal line (TL3) and the fourth signal line (TL4) may be electrically connected to a respective one of a pair of second subpixels (SP2). Each of the fifth signal line (TL5) and the sixth signal line (TL6) may be electrically connected to a respective one of a pair of third subpixels (SP3).

The first signal line (TL1) may be disposed on one side of a pair of first subpixels (SP1), and a second signal line (TL2) may be disposed on the other side of the pair of first subpixels (SP1). The first signal line (TL1) may be electrically connected to a first electrode (CE1) of one first subpixel (SP1) of the pair of first subpixels (SP1), for example, the 1-1-th subpixel (SP1a). The second signal line (TL2) may be electrically connected to a first electrode (CE1) of the other first subpixel (SP1) of the pair of first subpixels (SP1), for example, the 1-2-th subpixel (SP1b).

The third signal line (TL3) may be disposed on one side of a pair of second subpixels (SP2), and a fourth signal line (TL4) may be disposed on the other side of the pair of second subpixels (SP2). For example, the third signal line (TL3) may be arranged adjacent to the second signal line (TL2). The third signal line (TL3) may be electrically connected to a first electrode (CE1) of one second subpixel (SP2) of the pair of second subpixels (SP2), for example, the 2-1-th subpixel (SP2a). The fourth signal line (TL4) may be electrically connected to a first electrode (CE1) of the remaining second subpixel (SP2) of the pair of second subpixels (SP2), for example, the 2-2-th subpixel (SP2b).

The fifth signal line (TL5) may be disposed on one side of a pair of third subpixels (SP3), and a sixth signal line (TL6) may be disposed on the other side of the pair of third subpixels (SP3). For example, the fifth signal line (TL5) may be arranged adjacent to the fourth signal line (TL4). The sixth signal line (TL6) may be arranged adjacent to the first signal line (TL1) connected to the adjacent pixel (PX). The fifth signal line (TL5) may be electrically connected to a first electrode (CE1) of one third subpixel (SP3) of the pair of third subpixels (SP3), for example, the 3-1-th subpixel (SP3a). The sixth signal line (TL6) may be electrically connected to the first electrode (CE1) of the remaining third subpixel (SP3) among a pair of third subpixels (SP3), for example, the 3-2 subpixel (SP3b).

The plurality of signal lines (TL) may be formed of a conductive material. For example, the plurality of signal lines (TL) may be formed of a conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), etc., but the examples of the present disclosure are not limited thereto. For another example, the plurality of signal lines (TL) may be formed of a multilayer structure of conductive materials. For example, the plurality of signal lines (TL) may be formed of a multilayer structure of titanium (Ti)/aluminum (Al)/titanium (Ti)/indium tin oxide (ITO), but the examples of the present disclosure are not limited thereto.

The plurality of communication lines (NL) may be arranged in an area between a plurality of pixels (PX). The plurality of communication lines (NL) may be arranged to extend in a row direction in an area between the plurality of pixels (PX). The plurality of communication lines (NL) is disposed in an area between a plurality of second electrodes (CE2), and may not overlap the plurality of second electrodes (CE2). For example, the plurality of communication lines (NL) may be wires used for short-range communication such as NFC (Near Field Communication). The plurality of communication lines (NL) may function as antennas. For example, the plurality of communication lines (NL) may be a plurality of connection lines, but the examples of the present disclosure are not limited thereto.

According to the present disclosure, a bank (BNK) may be disposed in each of a plurality of subpixels. The plurality of banks (BNK) may be structures on which a plurality of light emitting elements (ED) are mounted. The plurality of banks (BNK) may guide positions of the plurality of light emitting elements (ED) in a transfer process for transferring the plurality of light emitting elements (ED). In the transfer process of the plurality of light emitting elements (ED), the plurality of light emitting elements (ED) may be transferred onto the plurality of banks (BNK). The entire area of the light emitting elements (ED) may overlap with the banks (BNK). The plurality of banks (BNK) may be bank patterns or structures, but the examples of the present disclosure are not limited thereto.

The bank (BNK) of the first subpixel (SP1), the bank (BNK) of the second subpixel (SP2), and the bank (BNK) of the third subpixel (SP3) may be arranged to be spaced apart from each other. The bank (BNK) of the first subpixel (SP1), the bank (BNK) of the second subpixel (SP2), and the bank (BNK) of the third subpixel (SP3) may be configured to be separated. Accordingly, the banks (BNK) of the first subpixel (SP1), the second subpixel (SP2), and the third subpixel (SP3), to which different types of light emitting elements (ED) are transferred, may be easily identified.

The bank (BNK) of the 1-1 subpixel (SP1a) and the bank (BNK) of the 1-2 subpixel (SP1b) may be connected to each other, or may be formed spaced apart from each other or separately. For example, considering the design of the transfer process requirements, etc., the bank (BNK) of the 1-1 subpixel (SP1a) and the bank (BNK) of the 1-2 subpixel (SP1b), in which the same light emitting element (ED) is disposed, may be connected to each other, or may be formed spaced apart from each other or separately. In addition, the bank (BNK) of the 2-1 subpixel (SP2a) and the bank (BNK) of the 2-2 subpixel (SP2b) may be connected to each other, or may be formed spaced apart from each other or separately. The bank (BNK) of the 3-1 subpixel (SP3a) and the bank (BNK) of the 3-2 subpixel (SP3b) may be connected to each other, or may be formed spaced apart from each other or separately. Accordingly, the bank (BNK) of the pair of first subpixels (SP1), the bank (BNK) of the pair of second subpixels (SP2), and the bank (BNK) of the pair of third subpixels (SP3) may be formed in various ways.

For example, the plurality of banks (BNK) may be formed of an organic insulating material. The plurality of banks (BNK) may be formed of a single layer or multiple layers of the organic insulating material. For example, the plurality of banks (BNK) may be formed of a photo resist, a polyimide (PI), or an acrylic material, but the examples of the present disclosure are not limited thereto.

The first electrode (CE1) may be disposed on each of a plurality of subpixels (SP). The first electrode (CE1) may be disposed on the bank (BNK) while overlapping the bank (BNK). The first electrode (CE1) may be electrically connected to one of the signal lines (TL) among the plurality of signal lines (TL). At least a portion of the first electrode (CE1) may extend outside the bank (BNK) and be electrically connected to the signal line (TL) closest to the first electrode (CE1). A portion of the first electrode (CE1) may overlap the bank (BNK), and the remainder of the first electrode (CE1) may not overlap the bank (BNK). For example, a part of the first electrode (CE1) of the 1-1 subpixel (SP1a) may extend to one side of the 1-1 subpixel (SP1a) and be electrically connected to the first signal line (TL1), a part of the first electrode (CE1) of the 1-2 subpixel (SP1b) may extend to the other side of the 1-2 subpixel (SP1b) and be electrically connected to the second signal line (TL2), a part of the first electrode (CE1) of the 2-1 subpixel (SP2a) may extend to one side of the 2-1 subpixel (SP2a) and be electrically connected to the third signal line (TL3), and a part of the first electrode (CE1) of the 2-2 subpixel (SP2b) may extend to the other side of the 2-2 subpixel (SP2b) and be electrically connected to the fourth signal line (TL4). A part of the first electrode (CE1) of the 3-1st subpixel (SP3a) may extend to one side of the 3-1st subpixel (SP3a) and be electrically connected to the fifth signal line (TL5), and a part of the first electrode (CE1) of the 3-second subpixel (SP3b) may extend to the other side of the 3-second subpixel (SP3b) and be electrically connected to the sixth signal line (TL6).

The first electrode (CE1) is electrically connected to the anode electrode (134 of FIG. 9) of the light emitting element (ED). An anode voltage from a pixel driving circuit (PD of FIG. 3) may be sequentially transmitted to the light emitting element (ED) via the signal line (TL) and the first electrode (CE1). Different voltages may be applied to the first electrode (CE1) of each of the plurality of subpixels according to an image to be displayed. For example, different voltages may be applied to the first electrode (CE1) of each of the plurality of subpixels. Accordingly, the first electrode (CE1) may be a pixel electrode, but the examples of the present disclosure are not limited thereto.

The first electrode (CE1) may be formed of a conductive material. For example, the first electrode (CE1) may be formed integrally with a plurality of signal lines (TL). For example, the first electrode (CE1) may be formed of the same conductive material as the plurality of signal lines (TL), but the examples of the present disclosure are not limited thereto. For example, the first electrode (CE1) may be formed of a conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), or the like, but the examples of the present disclosure are not limited thereto. For another example, the first electrode (CE1) may be formed of a multilayer structure of a conductive material. For example, the plurality of first electrodes (CE1) may be formed of a multilayer structure of titanium (Ti)/aluminum (Al)/titanium (Ti)/indium tin oxide (ITO), but the examples of the present disclosure are not limited thereto.

The light emitting element (ED) may be arranged in each of a plurality of subpixels (SP). The plurality of light emitting elements (ED) may be either a light emitting diode (LED) or a micro light emitting diode (micro-LED), but the examples of the present disclosure are not limited thereto. The plurality of light emitting elements (ED) may be disposed on the bank (BNK) and the first electrode (CE1) while overlapping the bank (BNK) and the first electrode (CE1). The entire area of the plurality of light emitting elements (ED) may overlap the bank (BNK) and the first electrode (CE1).

A plurality of light emitting elements (ED) are disposed on a first electrode (CE1) and may be electrically connected to the first electrode (CE1). Accordingly, the light emitting elements (ED) may emit light by receiving an anode voltage from a pixel driving circuit (PD) through a signal line (TL) and the first electrode (CE1).

The plurality of light emitting elements (ED) may include a first light emitting element (130), a second light emitting element (140), and a third light emitting element (150). The first light emitting element (130) may be disposed in a first subpixel (SP1). The second light emitting element (140) may be disposed in a second subpixel (SP2). The third light emitting element (150) may be disposed in a third subpixel (SP3). For example, one of the first light emitting element (130), the second light emitting element (140), and the third light emitting element (150) may be a red light emitting element, another may be a green light emitting element, and the rest may be blue light emitting elements, but the examples of the present disclosure are not limited thereto. Accordingly, red light, green light, and blue light emitted from the plurality of light emitting elements (ED) may be combined to implement light of various colors including white. The types of multiple light emitting elements (ED) are exemplary, and the examples of the present disclosure are not limited thereto.

The first light emitting element (130) may include a first light emitting element (130a) disposed in a 1-1 subpixel (SP1a) and a 1-2 light emitting element (130b) disposed in a 1-2 subpixel (SP1b). The second light emitting element (140) may include a 2-1 light emitting element (140a) disposed in a 2-1 subpixel (SP2a) and a 2-2 light emitting element (140b) disposed in a 2-2 subpixel (SP2b). The third light emitting element (150) may include a 3-1 light emitting element (150a) disposed in a 3-1 subpixel (SP3a) and a 3-2 light emitting element (150b) disposed in a 3-2 subpixel (SP3b).

A second electrode (CE2) may be disposed on each of a plurality of subpixels. The second electrode (CE2) may be disposed on a light emitting element (ED). The second electrode (CE2) may be electrically connected to a pixel driving circuit (PD of FIG. 3) through a plurality of contact electrodes (CCE).

For example, the second electrode (CE2) may be electrically connected to the cathode electrode (135 of FIG. 9) of the light emitting element (ED) to transmit the cathode voltage from the pixel driving circuit (PD of FIG. 3) to the light emitting element (ED). The same cathode voltage may be applied to the second electrode (CE2) of each of the plurality of subpixels (SP). For example, the same voltage may be applied to the second electrode (CE2) of each of the plurality of subpixels and the cathode electrode (135 of FIG. 9) of the light emitting element (ED). Accordingly, the second electrode (CE2) may be a common electrode, but the examples of the present disclosure are not limited thereto.

At least some of the plurality of subpixels may share the second electrode (CE2). At least some of the second electrodes (CE2) of each of the plurality of subpixels may be formed integrally and electrically connected. Since the same voltage is applied to the second electrodes (CE2), the second electrodes (CE2) of at least some of the subpixels may be shared and used. For example, the second electrodes (CE2) of at least some of the pixels (PX) among the plurality of pixels (PX) arranged in the same horizontal row may be formed integrally and connected to each other. For example, one second electrode (CE2) may be arranged for the plurality of pixels (PX). One second electrode (CE2) may be arranged for each of n subpixels (SP).

For example, some of the second electrodes (CE2) of the plurality of subpixels (SP) may be arranged to be spaced apart from or separated from each other. For example, the second electrode (CE2) connected to the pixels (PX) in the nth row and the second electrode (CE2) connected to the pixels (PX) in the (n+1)th row may be spaced apart or arranged separately. For example, the plurality of second electrodes (CE2) may be arranged to be spaced apart from each other with a plurality of communication lines (NL) extending in the row direction therebetween. Accordingly, the number of the plurality of subpixels (SP) may be greater than the number of the plurality of second electrodes (CE2). In another example, all of the second electrodes (CE2) of the plurality of subpixels may be integrally connected so that only one second electrode (CE2) is disposed on the substrate (110), but the examples of the present disclosure are not limited thereto.

The plurality of second electrodes (CE2) may be composed of a transparent conductive material, but the examples of the present disclosure are not limited thereto. The plurality of second electrodes (CE2) may be composed of a transparent conductive material so that light emitted from the light emitting element (ED) may be directed toward the upper portion of the second electrodes (CE2). For example, the second electrodes (CE2) may be composed of a transparent conductive material such as indium tin oxide (ITO), indium zinc oxide (IZO), indium gallium zinc oxide (IGZO), or the like, but the examples of the present disclosure are not limited thereto.

The plurality of contact electrodes (CCE) may be disposed on the substrate (110). For example, the plurality of contact electrodes (CCE) may be arranged spaced apart from the plurality of banks (BNK) and the plurality of signal lines (TL). Each of the plurality of second electrodes (CE2) may overlap at least one contact electrode (CCE). For example, one second electrode (CE2) may overlap the plurality of contact electrodes (CCE).

For example, a plurality of contact electrodes (CCE) may be electrically connected to a plurality of second electrodes (CE2). The plurality of contact electrodes (CCE) is disposed between the substrate (110) and the plurality of second electrodes (CE2) to transmit a cathode voltage from the pixel driving circuit (PD of FIG. 3) to the second electrodes (CE2).

For example, when using micro-LED as light emitting elements (ED), a plurality of micro-LEDs may be disposed on a wafer and the micro-LED may be transferred to a substrate (110) to manufacture a display panel (100). In the process of transferring a plurality of light emitting elements (ED) having a microscopic size from the wafer to the substrate (110), various defects may occur. For example, a non-transfer defect may occur in which the light emitting elements (ED) are not transferred in some subpixels, and a defect may occur in which the light emitting elements (ED) are transferred out of their proper positions due to alignment errors in other subpixels. In addition, the transfer process may proceed normally, but the transferred light emitting elements (ED) themselves may be defective. Therefore, in consideration of defects during the transfer process of the plurality of light emitting elements (ED), a plurality of light emitting elements (ED) of the same type may be transferred to one subpixel. A lighting test of the plurality of light emitting elements (ED) may be performed, and only one light emitting element (ED) that is ultimately determined to be normal may be used.

For example, the 1-1 light emitting element (130a) and the 1-2 light emitting element (130b) may be transferred together to one pixel (PX) and inspected for defects. If both the 1-1 light emitting element (130a) and the 1-2 light emitting element (130b) are determined to be normal, only the 1-1 light emitting element (130a) may be used and the 1-2 light emitting element (130b) may be unused. As another example, if only the 1-2 light emitting element (130b) among the 1-1 light emitting element (130a) and the 1-2 light emitting element (130b) is determined to be normal, the 1-1 light emitting element (130a) may be unused and only the 1-2 light emitting element (130b) may be used. Therefore, even if multiple light emitting elements (ED) of the same type are transferred to one pixel (PX), only one light emitting element (ED) may ultimately be used.

Accordingly, one of the pair of light emitting elements (ED) may be a main (or primary) light emitting element (ED), and the other light emitting element (ED) may be a redundancy light emitting element (ED). The redundancy light emitting element (ED) may be a spare light emitting element (ED) transferred in preparation for a failure of the main light emitting element (ED). In the event of a failure of the main light emitting element (ED), the redundancy light emitting element (ED) may be used as a replacement. Accordingly, by transferring the main light emitting element (ED) and the redundancy light emitting element (ED) together to one pixel (PX), it is possible to minimize a deterioration in display quality due to a failure of the main light emitting element (ED) and the redundancy light emitting element (ED).

For example, the 1-1 light emitting element (130a), the 2-1 light emitting element (140a), and the 3-1 light emitting element (150a) transferred to one pixel (PX) may be used as main light emitting elements (ED), and the 1-2 light emitting element (130b), the 2-2 light emitting element (140b), and the 3-2 light emitting element (150b) may be used as redundancy light emitting elements (ED).

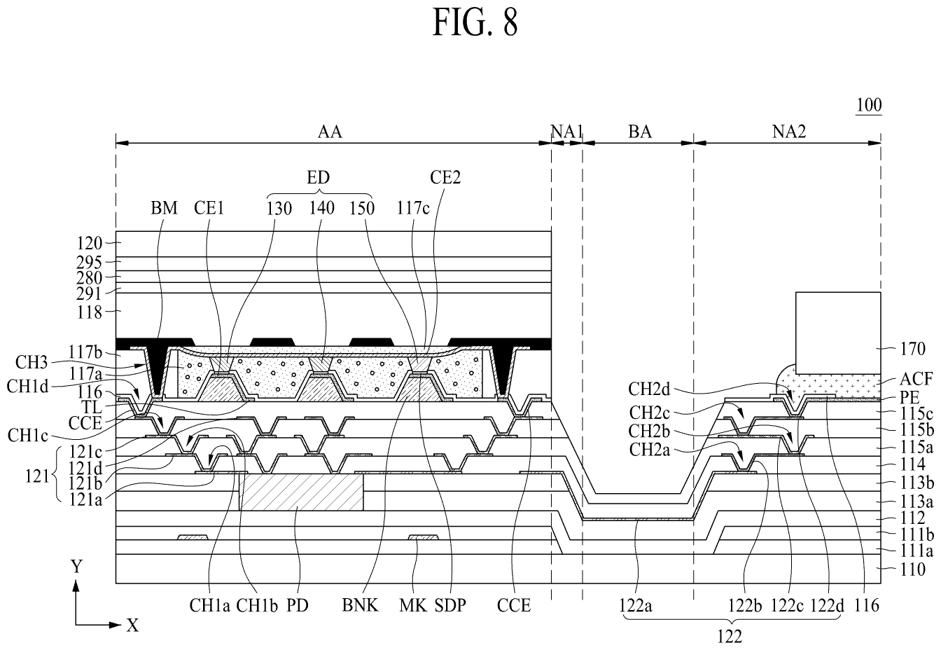

FIG. 8 is a cross-sectional view of the display panel (100) according to an example of the present disclosure. FIG. 9 is a cross-sectional view of the display device (100) according to an example of the present disclosure. For example, FIG. 8 is a cross-sectional view of the display area (AA), the first non-display area (NA1), the bending area (BA), and the second non-display area (NA2), and FIG. 9 is a cross-sectional view of a portion of the display area (AA).

Referring to FIG. 8, a first buffer layer (111a) and a second buffer layer (111b) may be disposed in the remaining area of the substrate (110) excluding the bending area (BA).

The first buffer layer (111a) and the second buffer layer (111b) may be disposed in the display area (AA), the first non-display area (NA1), and the second non-display area (NA2). The first buffer layer (111a) and the second buffer layer (111b) may reduce the penetration of moisture or impurities through the substrate (110). The first buffer layer (111a) and the second buffer layer (111b) may be formed of an inorganic insulating material. For example, the first buffer layer (111a) and the second buffer layer (111b) may be formed of a single layer or multiple layers of silicon oxide (SiOx) or silicon nitride (SiNx), but the examples of the present disclosure are not limited thereto.

For example, a portion of the first buffer layer (111a) and the second buffer layer (111b) on the bending area (BA) may be removed. The upper surface of the substrate (110) disposed on the bending area (BA) may be exposed without being covered by the first buffer layer (111a) and the second buffer layer (111b). By removing the first buffer layer (111a) and the second buffer layer (111b) made of an inorganic insulating material from the bending area (BA), cracks in the first buffer layer (111a) and the second buffer layer (111b) that may occur during bending may be minimized.

The plurality of alignment keys (MK) may be disposed between the first buffer layer (111a) and the second buffer layer (111b). The plurality of alignment keys (MK) may be configured to identify positions of pixel driving circuits (PD) during a manufacturing process of the display panel (100). For example, the plurality of alignment keys (MK) may be configured to align positions of pixel driving circuits (PD) transferred onto an adhesive layer (112). In another example, the plurality of alignment keys (MK) may be omitted.

An adhesive layer (112) may be disposed on the second buffer layer (111b). The adhesive layer (112) may be disposed in the display area (AA), the first non-display area (NA1), the bending area (BA), and the second non-display area (NA2). For another example, at least a portion of the adhesive layer (112) may be removed in the non-display areas (NA1, NA2) including the bending area (BA). For example, the adhesive layer (112) may be made of any one of: an adhesive polymer, an epoxy resin, a UV-curable resin, a polyimide series, an acrylate series, a urethane series, or a polydimethylsiloxane (PDMS), but the examples of the present disclosure are not limited thereto.

The pixel driving circuit (PD) may be disposed on the adhesive layer (112) in the display area (AA). When the pixel driving circuit (PD) is implemented as a display driving circuit, the display driving circuit may be mounted on the adhesive layer (112) by a transfer process, but the examples of the present disclosure are not limited thereto.

The first protective layer (113a) and a second protective layer (113b) may be disposed on the adhesive layer (112) and the pixel driving circuit (PD). The first protective layer (113a) and the second protective layer (113b) may be disposed to surround a side surface of the pixel driving circuit (PD), but the examples of the present disclosure are not limited thereto. For example, the second protective layer (113b) may be disposed to cover at least a portion of an upper surface of the pixel driving circuit (PD). For example, at least one of the first protective layer (113a) and the second protective layer (113b) disposed on the bending area (BA) may be omitted. For example, the first protective layer (113a) may be entirely disposed in the display area (AA) and the non-display area (NA), and the second protective layer (113b) may be partially disposed in the display area (AA), the first non-display area (NA1), and the second non-display area (NA2), and may not be disposed in the bending area (BA). For example, a portion of the second protective layer (113b) in the bending area (BA) may be removed. However, the examples of the present disclosure are not limited thereto.

The first protective layer (113a) and the second protective layer (113b) may be composed of an organic insulating material, but the examples of the present disclosure are not limited thereto. For example, the first protective layer (113a) and the second protective layer (113b) may be composed of a photo resist, a polyimide (PI), or a photo acryl-based material, but the examples of the present disclosure are not limited thereto. For example, the first protective layer (113a) and the second protective layer (113b) may be an overcoating layer or an insulating layer, but the examples of the present disclosure are not limited thereto.

According to the present disclosure, a plurality of first connection lines (121) may be disposed on the second protective layer (113b) in the display area (AA). The plurality of first connection lines (121) may be wires for electrically connecting the pixel driving circuit (PD) with other components. For example, the pixel driving circuit (PD) may be electrically connected to a plurality of signal lines (TL) and a plurality of contact electrodes (CCE), etc., through the plurality of first connection lines (121). For example, the plurality of first connection lines (121) may include a 1-1 connection line (121a), a 1-2 connection line (121b), a 1-3 connection line (121c), and a 1-4 connection line (121d), but the examples of the present disclosure are not limited thereto.

For example, a plurality of 1-1 connection lines (121a) may be disposed on the second protective layer (113b). The plurality of 1-1 connection lines (121a) may be electrically connected to a pixel driving circuit (PD). The plurality of 1-1 connection lines (121a) may transmit a voltage output from the pixel driving circuit (PD) to the first electrode (CE1) or the second electrode (CE2).

For example, a third protective layer (114) may be disposed on the second protective layer (113b). The third protective layer (114) may be disposed entirely in the display area (AA) and the non-display area (NA). In the bending area (BA), the third protective layer (114) may cover or enclose the side surface of the second protective layer (113b) and the upper surface of the first protective layer (113a). The third protective layer (114) may be composed of an organic insulating material. For example, the third protective layer (114) may be composed of a photoresist, a polyimide (PI), or a photo acryl-based material, but the examples of the present disclosure are not limited thereto. For example, the first protective layer (113a), the second protective layer (113b), and the third protective layer (114) may be composed of the same material. The examples of the present disclosure are not limited thereto.

The plurality of 1-1 contact holes (CH1a) and a plurality of 2-1 contact holes (CH2a) may be formed in the third protective layer (114). Specifically, the plurality of 1-1 contact holes (CH1a) may be formed in the display area (AA), and the plurality of 2-1 contact holes (CH2a) may be formed in the second non-display area (NA2). Some of the plurality of 1-1 contact holes (CH1a) may overlap with the pixel driving circuit (PD), and other some of the plurality of 1-1 contact holes (CH1a) may not overlap with the pixel driving circuit (PD). Some of the plurality of 1-1 contact holes (CH1a) overlapping with the pixel driving circuit (PD) may expose the upper surface of the pixel driving circuit (PD), and other some of the plurality of 1-1 contact holes (CH1a) not overlapping with the pixel driving circuit (PD) may expose the 1-1 connection line (121a).

The plurality of 1-2 connection lines (121b) may be disposed on the third protective layer (114). The plurality of 1-2 connection lines (121b) may be connected to the pixel driving circuit (PD) through the 1-1 connection lines (121a) or may be directly connected to the pixel driving circuit (PD). For example, a portion of the 1-2 connection lines (121b) may be directly connected to the pixel driving circuit (PD) through a portion of the plurality of 1-1 contact holes (CH1a) of the third protective layer (114). Another portion of the 1-2 connection lines (121b) may be electrically connected to the 1-1 connection lines (121a) through another portion of the plurality of 1-1 contact holes (CH1a) of the third protective layer (114).

However, the examples of the present disclosure are not limited thereto. For example, a voltage output from a pixel driving circuit (PD) may be transmitted to a first electrode (CE1) or a second electrode (CE2) through a plurality of 1-2 connection lines (121b) and other connection lines.

The first insulating layer (115a) may be disposed on a plurality of 1-2 connection lines (121b). The first insulating layer (115a) may be disposed entirely in the display area (AA) and the non-display area (NA), but the examples of the present disclosure are not limited thereto. The first insulating layer (115a) may be composed of an organic insulating material, but the examples of the present disclosure are not limited thereto. For example, the first insulating layer (115a) may be composed of a photo resist, a polyimide (PI), or a photo acryl-based material, but the examples of the present disclosure are not limited thereto.

The plurality of 1-2 contact holes (CH1b) and a plurality of 2-2 contact holes (CH2b) may be formed in the first insulating layer (115a). Specifically, a plurality of 1-2 contact holes (CH1b) may be formed in the display area (AA), and a plurality of 2-2 contact holes (CH2b) may be formed in the second non-display area (NA2). The plurality of 1-2 contact holes (CH1b) may expose upper surfaces of a plurality of 1-2 connection lines (121b).

A plurality of 1-3 connection lines (121c) may be disposed on the first insulating layer (115a). The plurality of 1-3 connection lines (121c) may be electrically connected to a plurality of 1-2 connection lines (121b). For example, the 1-3 connection line (121c) may be electrically connected to the 1-2 connection line (121b) through the 1-2 contact hole (CH1b) of the first insulating layer (115a).

The second insulating layer (115b) may be disposed on a plurality of 1-3 connection lines (121c). The second insulating layer (115b) may be disposed in an area other than the bending area (BA), but the examples of the present disclosure are not limited thereto. The second insulating layer (115b) may be disposed in the display area (AA), the first non-display area (NA1), and the second non-display area (NA2), but the examples of the present disclosure are not limited thereto. For example, at least a portion of the second insulating layer (115b) disposed in the bending area (BA) may be removed. The second insulating layer (115b) may be composed of an organic insulating material, but the examples of the present disclosure are not limited thereto. For example, the second insulating layer (115b) may be composed of a photoresist, polyimide (PI), or photo acryl material, but the examples of the present disclosure are not limited thereto.

The plurality of 1-3 contact holes (CH1c) and a plurality of 2-3 contact holes (CH2c) may be formed in the second insulating layer (115b). Specifically, a plurality of 1-3 contact holes (CH1c) may be formed in the display area (AA), and a plurality of 2-3 contact holes (CH2c) may be formed in the second non-display area (NA2). The plurality of 1-3 contact holes (CH1c) may expose upper surfaces of a plurality of 1-3 connection lines (121c).

A plurality of 1-4 connection lines (121d) may be disposed on the second insulating layer (115b). The plurality of 1-4 connection lines (121d) may be electrically connected to a plurality of 1-3 connection lines (121c). For example, the 1-4 connection line (121d) may be electrically connected to the 1-3 connection line (121c) through the 1-3 contact hole (CH1c) of the second insulating layer (115b).

According to the present disclosure, a plurality of second connection lines (122) may be disposed on the second protective layer (113b) in the non-display area (NA). The plurality of second connection lines (122) may be configured to deliver signals, which are transmitted from a flexible circuit board (or a flexible film) (170 in FIG. 2) and a printed circuit board (160 in FIG. 2) to a pad portion (PAD in FIG. 2), to the pixel driving circuit (PD) of the display area (AA).

For example, the plurality of second connection lines (122) may be electrically connected to a plurality of pad electrodes (PE), and may receive signals from a flexible circuit board (or a flexible film) (170 in FIG. 2) and a printed circuit board (160 in FIG. 2).

For example, a plurality of second connection lines (122) may extend from the pad portion (PAD of FIG. 2) toward the display area (AA) to transmit signals to the wiring of the display area (AA). In this case, the plurality of second connection lines (122) may function as link lines (LL of FIG. 3). The plurality of second connection lines (122) may include a 2-1 connection line (122a), a 2-2 connection line (122b), a 2-3 connection line (122c), and a 2-4 connection line (122d).

The plurality of 2-1 connection lines (122a) may be disposed on the second protective layer (113b). The plurality of 2-1 connection lines (122a) may extend from the second non-display area (NA2) to the bending area (BA) and the first non-display area (NA1). The plurality of 2-1 connection lines (122a) may transmit a signal transmitted from a flexible circuit board (or flexible film) (170 of FIG. 2) and a printed circuit board (160 of FIG. 2) to a pad portion (PAD of FIG. 2) to a pixel driving circuit (PD) of the display area (AA). Therefore, the plurality of 2-1 connection lines (122a) may be electrically connected to the pad electrode (PE) and the pixel driving circuit (PD), respectively.

The plurality of 2-2 connection lines (122b) may be disposed on the third protective layer (114). The plurality of 2-2 connection lines (122b) may be arranged in the second non-display area (NA2). The 2-2 connection lines (122b) may be electrically connected to the 2-1 connection lines (122a) through the 2-1 contact holes (CH2a) of the third protective layer (114). Accordingly, signals from the flexible circuit board (or flexible film) (170 in FIG. 2) and the printed circuit board (160 in FIG. 2) may be transmitted to the 2-1 connection lines (122a) through the 2-2 connection lines (122b).

The 2-3 connection line (122c) may be disposed on the first insulating layer (115a). The 2-3 connection line (122c) may be arranged in the second non-display area (NA2). The 2-3 connection line (122c) may be electrically connected to the 2-2 connection line (122b) through the 2-2 contact hole (CH2b) of the first insulating layer (115a). Accordingly, signals from the flexible circuit board (or flexible film) (170 in FIG. 2) and the printed circuit board (160 in FIG. 2) may be transmitted to the 2-1 connection line (122a) through the 2-3 connection line (122c) and the 2-2 connection line (122b).

A 2-4 connection wiring (122d) may be disposed on the second insulating layer (115b). The 2-4 connection wiring (122d) may be disposed in the second non-display area (NA2). The 2-4 connection line (122d) may be electrically connected to a 2-3 connection wiring (122c) through a 2-3 contact hole (CH2c) of the second insulating layer (115b). Accordingly, signals from the flexible circuit board (or flexible film) (170 in FIG. 2) and the printed circuit board (160 in FIG. 2) may be delivered to the 2-1 connection line (122a) via the 2-4 connection line (122d), the 2-3 connection wiring (122c), and the 2-2 connection wiring (122b).

The plurality of first connection lines (121) and the plurality of second connection lines (122) may be formed of any one of a conductive material having excellent ductility or various conductive materials used in the display area (AA). For example, the second connection lines (122), a portion of which is disposed in the bending area (BA), may be formed of a conductive material having excellent ductility, such as gold (Au), silver (Ag), or aluminum (Al), but the examples of the present disclosure are not limited thereto. As another example, the plurality of first connection lines (121) and the plurality of second connection lines (122) may be formed of molybdenum (Mo), chromium (Cr), titanium (Ti), nickel (Ni), neodymium (Nd), copper (Cu), and an alloy of silver (Ag) and magnesium (Mg), or an alloy thereof, but the examples of the present disclosure are not limited thereto.

The third insulating layer (115c) may be disposed on a plurality of first connection lines (121) and a plurality of second connection lines (122). The third insulating layer (115c) may be disposed in an area other than the bending area (BA), but the examples of the present disclosure are not limited thereto. The third insulating layer (115c) may be disposed in the display area (AA), the first non-display area (NA1), and the second non-display area (NA2). At least a portion of the third insulating layer (115c) in the bending area (BA) may be removed. The third insulating layer (115c) may be composed of an organic insulating material, but the examples of the present disclosure are not limited thereto. For example, the third insulating layer (115c) may be composed of a photo resist, polyimide (PI), or photo acryl material, but the examples of the present disclosure are not limited thereto.

The plurality of 1-4 contact holes (CH1d) and a plurality of 2-4 contact holes (CH2d) may be formed in the third insulating layer (115c). Specifically, a plurality of 1-4 contact holes (CH1d) may be formed in the display area (AA), and a plurality of 2-4 contact holes (CH2d) may be formed in the second non-display area (NA2). A plurality of 1-4 contact holes (CH1d) may expose upper surfaces of a plurality of 1-4 connection lines (121d), and a plurality of 2-5 contact holes (CH2d) may expose upper surfaces of a plurality of 2-4 connection lines (122d).

A plurality of banks (BNK) may be disposed on the third insulating layer (115c) in the display area (AA). The plurality of banks (BNK) may be arranged to overlap each of the plurality of subpixels. The plurality of banks (BNK) may not be disposed in the first non-display area (NA1), the second non-display area (NA2), and the bending area (BA). At least one light emitting element (ED) of the same type may be disposed on each of the plurality of banks (BNK).

The plurality of signal lines (TL) may be disposed on the third insulating layer (115c) in the display area (AA). The plurality of signal lines (TL) may be disposed in an area between the plurality of banks (BNK). For example, the plurality of signal lines (TL) may be arranged adjacent to any one of the plurality of banks (BNK). Each of the plurality of signal lines (TL) may be electrically connected to a first connection line (121), for example, a 1-4 connection line (121d).

A plurality of contact electrodes (CCE) may be disposed on the third insulating layer (115c) in the display area (AA). The plurality of contact electrodes (CCE) may supply a cathode voltage from the pixel driving circuit (PD) to the second electrode (CE2). Each of the plurality of contact electrodes (CCE) may be electrically connected to a first connection line (121), for example, a 1-4 connection line (121d), through a 1-4 contact hole (CH1d).

The first electrode (CE1) may be disposed on the bank (BNK). For example, the first electrode (CE1) may be arranged to extend from an adjacent signal line (TL) toward an upper portion of the bank (BNK). The first electrode (CE1) may be disposed on an upper surface of the bank (BNK) and a side surface of the bank (BNK). For example, the first electrode (CE1) may be arranged to extend from the signal line (TL) on an upper surface of the third insulating layer (115c) to the side surface of the bank (BNK) and the upper surface of the bank (BNK). The first electrode (CE1) may be formed integrally with the signal line (TL).

Referring to FIG. 9, the first electrode (CE1) may be composed of a plurality of conductive layers. For example, the first electrode (CE1) may include a first conductive layer (CE1a), a second conductive layer (CE1b), a third conductive layer (CE1c), and a fourth conductive layer (CE1d), but the examples of the present disclosure are not limited thereto.

The first conductive layer (CE1a) may be disposed on the bank (BNK). The second conductive layer (CE1b) may be disposed on the first conductive layer (CE1a). The third conductive layer (CE1c) may be disposed on the second conductive layer (CE1b), and the fourth conductive layer (CE1d) may be disposed on the third conductive layer (CE1c). For example, each of the first conductive layer (CE1a), the second conductive layer (CE1b), the third conductive layer (CE1c), and the fourth conductive layer (CE1d) may be composed of titanium (Ti), molybdenum (Mo), aluminum (Al), or titanium (Ti) and indium tin oxide (ITO), but the examples of the present disclosure are not limited thereto.

According to the present disclosure, among the plurality of conductive layers constituting the first electrode (CE1), some of the conductive layers having high reflection efficiency may be configured as an alignment key and/or a reflector for aligning the light emitting element (ED). For example, among the plurality of conductive layers of the first electrode (CE1), the second conductive layer (CE1b) may include a reflective material. For example, the second conductive layer (CE1b) may include aluminum (Al), but the examples of the present disclosure are not limited thereto. Accordingly, the second conductive layer (CE1b) may be configured as a reflector. In addition, due to the high reflection efficiency of the second conductive layer (CE1b), it may be easily identified in a manufacturing process, and thus the position or transfer position of the light emitting element (ED) may be aligned based on the second conductive layer (CE1b).

For example, in order to configure the second conductive layer (CE1b) as a reflector, the third conductive layer (CE1c) and the fourth conductive layer (CE1d) covering the second conductive layer (CE1b) may be partially removed or etched. For example, a portion of the third conductive layer (CE1c) and the fourth conductive layer (CE1d) disposed on the bank (BNK) may be removed or etched to expose the upper surface of the second conductive layer (CE1b). For example, the central portion and the border portion (or edge portion) of the third conductive layer (CE1c) and the fourth conductive layer (CE1d) on which the solder pattern (SDP) is disposed may be left, and the remaining portion may be removed. For example, the edge portion (or edge portion) and the center portion of each of the third conductive layer (CE1c) made of titanium (Ti) and the fourth conductive layer (CE1d) made of indium tin oxide (ITO) may not be etched. Accordingly, it is possible to prevent other conductive layers of the first electrode (CE1) from being corroded by the TMAH (Tetra-Methyl-Ammonium-Hydroxide) solution used in the mask process of the first electrode (CE1).

According to the present disclosure, the first conductive layer (CE1a) and the third conductive layer (CE1c) may include titanium (Ti) or molybdenum (Mo). The second conductive layer (CE1b) may include aluminum (Al). The fourth conductive layer (CE1d) may include a transparent conductive oxide layer, such as indium tin oxide (ITO) or indium zinc oxide (IZO), which has good adhesion to the solder pattern (SDP) and has corrosion resistance and acid resistance. However, the examples of the present disclosure are not limited thereto.

The first conductive layer (CE1a), the second conductive layer (CE1b), the third conductive layer (CE1c), and the fourth conductive layer (CE1d) may be sequentially deposited and then patterned by performing a photolithography process and an etching process, but the examples of the present disclosure are not limited thereto.

As may be seen in FIGS. 8 and 9, according to the present disclosure, the signal wiring (TL), the contact electrode (CCE), and the pad electrode (PE) disposed on the same layer as the first electrode (CE1) may be composed of multiple layers of conductive materials, but the examples of the present disclosure are not limited thereto. For example, the signal line (TL), the contact electrode (CCE), and the pad electrode (PE) may be composed of multiple layers of indium tin oxide (ITO)/titanium (Ti)/aluminum (Al)/titanium (Ti), but the examples of the present disclosure are not limited thereto.

According to the present disclosure, a solder pattern (SDP) may be disposed on a first electrode (CE1) in each of a plurality of subpixels. The solder pattern (SDP) may bond a light emitting element (ED) to the first electrode (CE1). The first electrode (CE1) and the light emitting element (ED) may be electrically connected through eutectic bonding using the solder pattern (SDP), but the examples of the present disclosure are not limited thereto. For example, when the solder pattern (SDP) is made of indium (In) and the anode electrode (134) of the light emitting element (ED) is made of gold (Au), the solder pattern (SDP) and the anode electrode (134) may be bonded by applying heat and pressure in a transfer process of the light emitting element (ED). Through eutectic bonding, the light emitting element (ED) may be bonded to the solder pattern (SDP) and the first electrode (CE1) without a separate adhesive. For example, the solder pattern (SDP) may be composed of indium (In), tin (Sn) or an alloy thereof, but the examples of the present disclosure are not limited thereto. For example, the solder pattern (SDP) may be a bonding pad or a bonding pad, but the examples of the present disclosure are not limited thereto.

According to the present disclosure, the passivation layer (116) may be disposed on a plurality of signal lines (TL), a plurality of first electrodes (CE1), a plurality of contact electrodes (CCE), and a third insulating layer (115c). For example, the passivation layer (116) may be disposed in the display area (AA), the first non-display area (NA1), and the second non-display area (NA2). At least a portion of the passivation layer (116) disposed in the bending area (BA) may be removed. A portion of the passivation layer (116) covering the plurality of pad electrodes (PE) in the second non-display area (NA2) may be removed. A portion of the passivation layer (116) covering the plurality of contact electrodes (CCE) in the display area (AA) may be removed. A passivation layer (116) covering the solder pattern (SDP) in the display area (AA) may be removed. The passivation layer (116) may cover the first electrode (CE1). The passivation layer (116) may cover a portion of the upper surface of the exposed second conductive layer (CE1b).

The passivation layer (116) is arranged to expose at least a portion of the plurality of pad electrodes (PE), the plurality of contact electrodes (CCE), and the solder pattern (SDP) while covering the remaining area, so as to reduce the penetration of moisture or impurities into the light emitting element (ED). For example, the passivation layer (116) may be composed of a single layer or multiple layers of silicon oxide (SiOx) or silicon nitride (SiNx), but the examples of the present disclosure are not limited thereto. For example, the passivation layer (116) may be a protective layer or an insulating layer, but the examples of the present disclosure are not limited thereto. For example, the passivation layer (116) may include a hole exposing the solder pattern (SDP) and a hole exposing the contact electrode (CCE). The hole exposing the solder pattern (SDP) may be a 2-4 contact hole (CH2d), and the hole exposing the contact electrode (CCE) may be a third contact hole (CH3).

The light emitting element (ED) may be disposed on a solder pattern (SDP) in each of a plurality of subpixels. A first light emitting element (130) may be arranged in a first subpixel (SP1). A second light emitting element (140) may be arranged in a second subpixel (SP2). A third light emitting element (150) may be arranged in a third subpixel (SP3).

The light emitting element (ED) may be disposed on a silicon wafer by a method such as Metal Organic Chemical Vapor Deposition (MOCVD), Chemical Vapor Deposition (CVD), Plasma-Enhanced Chemical Vapor Deposition (PECVD), Molecular Beam Epitaxy (MBE), Hydride Vapor Phase Epitaxy (HVPE), or sputtering, but the examples of the present disclosure are not limited thereto.

Referring to FIG. 9, the first light emitting element (130) may include an anode electrode (134), a first semiconductor layer (131), an active layer (132), a second semiconductor layer (133), a cathode electrode (135), and a sealing layer (136), but the examples of the present disclosure are not limited thereto. For example, the first light emitting element (130) may not include a sealing layer (136).

A first semiconductor layer (131) may be disposed on a solder pattern (SDP). A second semiconductor layer (133) may be disposed on the first semiconductor layer (131).

For example, one of the first semiconductor layer (131) and the second semiconductor layer (133) may be implemented as a compound semiconductor of group III-V or group II-VI, and may be doped with an impurity (or dopant). One of the first semiconductor layer (131) and the second semiconductor layer (133) may be doped with an n-type impurity, and the other may be doped with a p-type impurity. However, the examples of the present disclosure are not limited thereto. For instance, one or both of the first semiconductor layer (131) and the second semiconductor layer (133) may be a layer in which an n-type or p-type impurity is doped into a material such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), or gallium arsenide (GaAs), but are not limited thereto. Examples of n-type impurities may include silicon (Si), germanium (Ge), selenium (Se), carbon (C), tellurium (Te), or tin (Sn), but are not limited thereto. Examples of p-type impurities may include magnesium (Mg), zinc (Zn), calcium (Ca), strontium (Sr), barium (Ba), or beryllium (Be), but are not limited thereto.

For example, the first semiconductor layer (131) and the second semiconductor layer (133) may be a nitride semiconductor including an n-type impurity and a nitride semiconductor including a p-type impurity, respectively, but the examples of the present disclosure are not limited thereto. For example, the first semiconductor layer (131) may be a nitride semiconductor including a p-type impurity, and the second semiconductor layer (133) may be a nitride semiconductor including an n-type impurity, but the examples of the present disclosure are not limited thereto.

The active layer (132) may be disposed between the first semiconductor layer (131) and the second semiconductor layer (133). The active layer (132) may receive holes and electrons from the first semiconductor layer (131) and the second semiconductor layer (133) to emit light. For example, the active layer (132) may be configured as one of a single well structure, a multi-well structure, a single quantum well structure, a multi-quantum well (MQW) structure, a quantum dot structure, and a quantum wire structure, but the examples of the present disclosure are not limited thereto. For example, the active layer (132) may be configured as indium gallium nitride (InGaN) or gallium nitride (GaN), but the examples of the present disclosure are not limited thereto.

As another example, the active layer (132) may include a multi-quantum well (MQW) structure having a well layer and a barrier layer having a higher band gap than the well layer. For example, the active layer (132) may include InGaN as a well layer and an AlGaN layer as a barrier layer, but the examples of the present disclosure are not limited thereto.

The anode electrode (134) may be disposed between the first semiconductor layer (131) and the solder pattern (SDP). For example, the anode electrode (134) may electrically connect the first semiconductor layer (131) and the first electrode (CE1). The anode voltage output from the pixel driving circuit (PD) may be applied to the first semiconductor layer (131) through the signal line (TL), the first electrode (CE1), and the anode electrode (134). For example, the anode electrode (134) may be composed of a conductive material capable of eutectic bonding with the solder pattern (SDP), but the examples of the present disclosure are not limited thereto. For example, the anode electrode (134) may be composed of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), and copper (Cu), or alloys thereof, but the examples of the present disclosure are not limited thereto.

The cathode electrode (135) may be disposed on the second semiconductor layer (133). For example, the cathode electrode (135) may electrically connect the second semiconductor layer (133) and the second electrode (CE2). A cathode voltage output from the pixel driving circuit (PD) may be applied to the second semiconductor layer (133) through the contact electrode (CCE), the second electrode (CE2), and the cathode electrode (135). The cathode electrode (135) may be formed of a transparent conductive material so that light emitted from the light emitting element (ED) can be directed toward the upper side of the light-emitting element (ED). However, the examples of the present disclosure are not limited thereto. For example, the cathode electrode (135) may be composed of a material such as indium tin oxide (ITO), indium zinc oxide (IZO), or indium gallium zinc oxide (IGZO), but the examples of the present disclosure are not limited thereto.

The sealing layer (136) may be disposed on at least a portion of the first semiconductor layer (131), the active layer (132), the second semiconductor layer (133), the anode electrode (134), and the cathode electrode (135). For example, the sealing layer (136) may surround at least a portion of the first semiconductor layer (131), the active layer (132), the second semiconductor layer (133), the anode electrode (134), and the cathode electrode (135).

For example, the sealing layer (136) may protect the first semiconductor layer (131), the active layer (132), and the second semiconductor layer (133). For example, the sealing layer (136) may be disposed on the side surface of the first semiconductor layer (131), the side surface of the active layer (132), and the side surface of the second semiconductor layer (133).

For example, the sealing layer (136) may be disposed on at least a portion of the anode electrode (134) and the cathode electrode (135), for example, an edge portion (or an edge portion or one side) of the anode electrode (134) and an edge portion (or an edge portion or one side) of the cathode electrode (135). At least a portion of the anode electrode (134) that is not covered by the sealing layer (136) may be exposed so that the anode electrode (134) and the solder pattern (SDP) may be connected. For example, at least a portion of the cathode electrode (135) that is not covered by the sealing layer (136) may be exposed so that the cathode electrode (135) and the second electrode (CE2) may be connected. For example, the sealing layer (136) may be made of an insulating material such as silicon nitride (SiNx) or silicon oxide (SiOx), but the examples of the present disclosure are not limited thereto.

For another example, the sealing layer (136) may have a structure in which a reflective material is dispersed in a resin layer, but the examples of the present disclosure are not limited thereto. For example, the sealing layer (136) may be manufactured as a reflector of various structures, but the examples of the present disclosure are not limited thereto. Light emitted from the active layer (132) by the sealing layer (136) may be reflected upward, thereby improving light extraction efficiency. For example, the sealing layer (136) may be a reflective layer, but the examples of the present disclosure are not limited thereto.

According to this disclosure, the light emitting element (ED) is described as having a vertical structure, but the examples of this disclosure are not limited thereto. For example, the light emitting element (ED) may have a lateral structure or a flip chip structure.

Although the first light emitting element (130) has been described with reference to FIG. 9, the second light emitting element (140) and the third light emitting element (150) may have substantially the same structure as the first light emitting element (130). For example, the second light emitting element (140) and the third light emitting element (150) may include substantially the same configuration as the first semiconductor layer (131), the active layer (132), the second semiconductor layer (133), the anode electrode (134), the cathode electrode (135), and the sealing layer (136) of the first light emitting element (130).

As may be seen in FIGS. 8 and 9, according to the present disclosure, a first optical layer (117a) may be arranged to surround a plurality of light emitting elements (ED) in a display area (AA). For example, the first optical layer (117a) may be disposed to cover side surfaces of the plurality of light emitting elements (ED) and side surfaces of the plurality of banks (BNK) in areas of the plurality of subpixels. For example, the first optical layer (117a) may cover a portion of the passivation layer (116). For example, the first optical layer (117a) may cover a second electrode (CE2), a portion of the passivation layer (116), and between the plurality of light emitting elements (ED). The first optical layer (117a) may be arranged or cover between the plurality of light emitting elements (ED) included in one pixel (PX) and between the plurality of banks (BNK). For example, the first optical layer (117a) may extend in the first direction (X), and a plurality of first optical layers (117a) may be arranged to be spaced apart from each other in the second direction (Y) in a plan view. For example, the first optical layer (117a) may be arranged to surround the side of the light emitting element (ED) and the bank (BNK) between the passivation layer (116) and the second electrode (CE2), but the examples of the present disclosure are not limited thereto. For example, the first optical layer (117a) may be a diffusion layer or a sidewall diffusion layer, but the examples of the present disclosure are not limited thereto.

The first optical layer (117a) may include an organic insulating material having fine particles dispersed therein, but the examples of the present disclosure are not limited thereto. For example, the first optical layer (117a) may be composed of siloxane having fine metal particles, such as titanium dioxide (TiO2) particles, dispersed therein, but the examples of the present disclosure are not limited thereto. Light from a plurality of light emitting elements (ED) may be scattered by the fine particles dispersed in the first optical layer (117a) and emitted to the outside of the display panel (100). Accordingly, the first optical layer (117a) may improve the extraction efficiency of light emitted from the plurality of light emitting elements (ED).

For example, the first optical layer (117a) may be arranged in each of the plurality of pixels (PX), or may be arranged together in some of the pixels (PX) arranged in the same row, but the examples of the present disclosure are not limited thereto. For example, the first optical layer (117a) may be arranged in each of the plurality of pixels (PX), or the plurality of pixels (PX) may share one first optical layer (117a). For another example, each of the plurality of subpixels may separately include the first optical layer (117a), but the examples of the present disclosure are not limited thereto.

According to the present disclosure, a second optical layer (117b) may be disposed on the passivation layer (116) in the display area (AA). For example, the second optical layer (117b) may be disposed to surround the first optical layer (117a). For example, the second optical layer (117b) may contact a side surface of the first optical layer (117a). For example, the second optical layer (117b) may be disposed in an area between a plurality of pixels (PX). However, the examples of the present disclosure are not limited thereto. For example, the second optical layer (117b) may be a diffusion layer, a diffusion layer window, or a window diffusion layer, but the examples of the present disclosure are not limited thereto.

The second optical layer (117b) may be composed of an organic insulating material, but the examples of the present disclosure are not limited thereto. The second optical layer (117b) may be composed of the same material as the first optical layer (117a), but the examples of the present disclosure are not limited thereto. For example, the first optical layer (117a) may include fine particles, and the second optical layer (117b) may not include fine particles. For example, the second optical layer (117b) may be composed of siloxane, but the examples of the present disclosure are not limited thereto.

For example, the thickness of the first optical layer (117a) may be smaller than the thickness of the second optical layer (117b), but the examples of the present disclosure are not limited thereto. Accordingly, when viewed from a planar surface, the area where the first optical layer (117a) is disposed may include a concave portion that is sunken inwardly more than the upper surface of the second optical layer (117b).

The plurality of third contact holes (CH3) may be formed in the second optical layer (117b). The plurality of third contact holes (CH3) may expose the upper surfaces of the plurality of contact electrodes (CCE).

According to the present disclosure, a second electrode (CE2) may be disposed on the first optical layer (117a) and the second optical layer (117b). For example, the second electrode (CE2) may be electrically connected to a plurality of contact electrodes (CCE) through a plurality of third contact holes (CH3) of the second optical layer (117b). For example, the second electrode (CE2) may be disposed on a plurality of light emitting elements (ED). For example, the second electrode (CE2) may include a transparent conductive oxide such as indium tin oxide (ITO) or indium zinc oxide (IZO), but the examples of the present disclosure are not limited thereto. For example, the second electrode (CE2) may be disposed to be in contact with the cathode electrode (135). For example, the second electrode (CE2) may overlap the entirety of the first optical layer (117a) and may overlap a portion of the second optical layer (117b).

The second electrode (CE2) may be continuously extended in the first direction of the substrate (110). Accordingly, the second electrode (CE2) may be commonly connected to a plurality of pixels (PX) arranged in the first direction of the substrate (110). For example, the second electrode (CE2) may be commonly connected to a plurality of pixels (PX).

According to the present disclosure, the second electrode (CE2) may be continuously extended over the first optical layer (117a), the second optical layer (117b), and the light emitting element (ED). The region where the first optical layer (117a) is disposed may include a concave portion that is sunken inwardly more than an upper surface of the second optical layer (117b). Accordingly, the first portion of the second electrode (CE2) disposed on the first optical layer (117a) is disposed along the concave portion, and thus may be disposed at a lower position than the second portion of the second electrode (CE2) disposed on the second optical layer (117b).

The third optical layer (117c) may be disposed on the second electrode (CE2). The third optical layer (117c) may be disposed so as to overlap the plurality of light emitting elements (ED) and the first optical layer (117a). For example, the third optical layer (117c) may be disposed so as not to overlap the second optical layer (117b). Since the third optical layer (117c) is disposed on the second electrode (CE2) and the plurality of light emitting elements (ED), it is possible to improve a stain (Mura) that may occur on some of the plurality of light emitting elements (ED). For example, when transferring the plurality of light emitting elements (ED) onto the substrate (110) of the display panel (100), regions in which the spacing between the plurality of light emitting elements (ED) is not uniform may occur due to process variations or the like. When the spacing between the plurality of light emitting elements (ED) is uneven, the light emitting areas of each of the plurality of light emitting elements (ED) may be arranged unevenly, which may cause a stain (mura) to be visible to the user. Accordingly, since a third optical layer (117c) configured to uniformly diffuse light is formed over the plurality of light emitting elements (ED), it is possible to reduce the light emitted from some of the light emitting elements (ED) from being visible as a stain. Accordingly, since the light emitted from the plurality of light emitting elements (ED) is evenly diffused by the third optical layer (117c) and extracted to the outside of the display panel (100), the brightness uniformity of the display device (1000) may be improved.

The third optical layer (117c) may be composed of an organic insulating material having fine particles dispersed therein, but the examples of the present disclosure are not limited thereto. For example, the third optical layer (117c) may be composed of siloxane having fine metal particles, such as titanium dioxide (TiO2) particles, dispersed therein, but the examples of the present disclosure are not limited thereto. For example, the third optical layer (117c) may be composed of the same material as the first optical layer (117a), but the examples of the present disclosure are not limited thereto. For example, the third optical layer (117c) may be a diffusion layer or a top diffusion layer, but the examples of the present disclosure are not limited thereto.

According to the present disclosure, light from a plurality of light emitting elements (ED) may be scattered by fine particles dispersed in a third optical layer (117c) and emitted to the outside of the display panel (100). The third optical layer (117c) may evenly mix the light emitted from the plurality of light emitting elements (ED), thereby further improving the brightness uniformity of the display device (1000). In addition, the light extraction efficiency of the display device (1000) may be improved by the light scattered from the plurality of fine particles, and thus the display device (1000) may be driven at low power.

The black matrix (BM) may be disposed on the second electrode (CE2), the first optical layer (117a), the second optical layer (117b), and the third optical layer (117c) in the display area (AA). For example, the black matrix (BM) may fill the third contact hole (CH3) of the second optical layer (117b). Since the black matrix (BM) is configured to cover the display area (AA), it is possible to reduce color mixing of light and external light reflection of a plurality of subpixels. For example, since the black matrix (BM) is also arranged in the third contact hole (CH3) where the second electrode (CE2) and the contact electrode (CCE) are connected, it is possible to prevent light leakage between neighboring a plurality of subpixels.

For example, the black matrix (BM) may be composed of an opaque material, but the examples of the present disclosure are not limited thereto. For example, the black matrix (BM) may be an organic insulating material to which a black pigment or black dye is added, but the examples of the present disclosure are not limited thereto.

Referring to FIG. 8, a cover layer (118) may be disposed on a black matrix (BM) in a display area (AA). The cover layer (118) may protect a configuration under the cover layer (118). For example, the cover layer (118) may be composed of an organic insulating material, but the examples of the present disclosure are not limited thereto. For example, the cover layer (118) may be composed of a photo resist, a polyimide (PI), or a photo acryl-based material, but the examples of the present disclosure are not limited thereto. For example, the cover layer (118) may be an overcoating layer or an insulating layer, but the examples of the present disclosure are not limited thereto.

The polarizing layer (280) may be disposed on the cover layer (118) via a first adhesive layer (291). A cover member (120) may be disposed on the polarizing layer (280) via a second adhesive layer (295). For example, the first adhesive layer (291) and the second adhesive layer (295) may include an optically clear adhesive (OCA), an optically clear resin (OCR), or a pressure sensitive adhesive (PSA), but the examples of the present disclosure are not limited thereto.

According to the present disclosure, a plurality of pad electrodes (PE) may be disposed on a third insulating layer (115c) in a second non-display area (NA2). For example, at least a portion of the plurality of pad electrodes (PE) may be exposed without being covered by the passivation layer (116). For example, the plurality of pad electrodes (PE) may be electrically connected to a 2-4 connection line (122d) through a 2-4 contact hole (CH2d) of the third insulating layer (115c).

An anisotropic conductive film (ACF) may be disposed on a plurality of pad electrodes (PE). The anisotropic conductive film (ACF) may be an adhesive layer in which conductive balls are dispersed on an insulating material, but the examples of the present disclosure are not limited thereto. When heat or pressure is applied to the anisotropic conductive film (ACF), the conductive balls may be electrically connected at a portion where the heat or pressure is applied so as to have conductive properties. By disposing the anisotropic conductive film (ACF) between the plurality of pad electrodes (PE) and a flexible circuit board (or flexible film) (170), the flexible circuit board (or flexible film) (170) may be attached or bonded to the plurality of pad electrodes (PE). For example, the anisotropic conductive film (ACF) may be an anisotropic conductive film (ACF), but the examples of the present disclosure are not limited thereto.

The flexible circuit board (or flexible film) (170) may be disposed on an anisotropic conductive film (ACF). The flexible circuit board (or flexible film) (170) may be electrically connected to a plurality of pad electrodes (PE) through the anisotropic conductive film (ACF). Accordingly, signals output from the flexible circuit board (or flexible film) (170) and the printed circuit board may be transmitted to a pixel driving circuit (PD) of a display area (AA) through a plurality of pad electrodes (PE), a 2-4 connection line (122d), a 2-3 connection line (122c), a 2-2 connection line (122b), and a 2-1 connection line (122a).

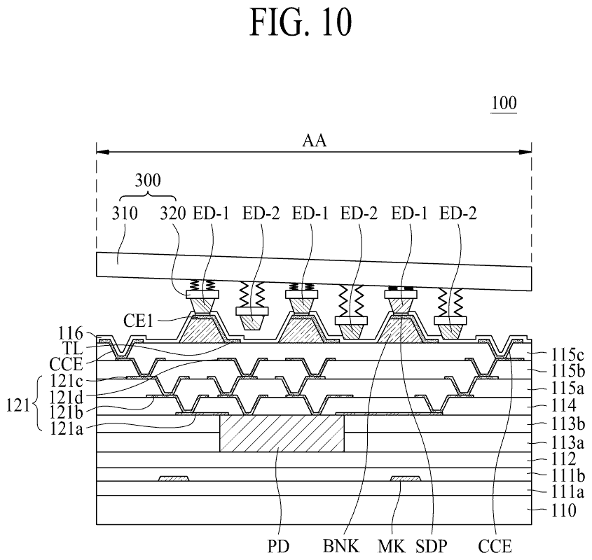

FIG. 10 is a process cross-sectional view illustrating a transfer process of a light emitting element (ED) according to an example of the present disclosure.

As may be seen in FIG. 10, a plurality of light emitting elements (ED-1, ED-2) fixed to the transfer device (300) may be transferred to individual subpixels of the display area (AA) after moving upwards on the display panel (100).

The transfer device (300) may include a support member (310) and a plurality of pickers (320) connected to the support member (310). A plurality of light emitting elements (ED-1, ED-2) are fixed to the plurality of pickers (320), and the plurality of light emitting elements (ED-1, ED-2) may be moved above the display area (AA) of the display panel (100) while being fixed by the plurality of pickers (320) and then transferred onto a plurality of solder patterns (SDP) disposed on the bank (BNK).

In transferring the plurality of light emitting elements (ED-1, ED-2), the transfer process may be sequentially performed by increasing the transfer speed using a plurality of pickers (320) to lift multiple light-emitting elements (ED-1, ED-2) at once (single pick), followed by multiple transfers (multi place). For example, a first set of a plurality of light emitting elements (ED-1) may be transferred onto a plurality of solder patterns (SDP) disposed on a plurality of banks (BNK) of the first set through a first transfer process, and a second set of a plurality of light emitting elements (ED-2) that are not transferred may be moved to a corresponding position by a transfer device (300) and then transferred onto a plurality of solder patterns (SDP) disposed on a plurality of banks (BNK) of the second set through a second transfer process.

At this time, the spacing between the plurality of pickers (320) is configured to be smaller than the spacing between the plurality of banks (BNK), so that when the transfer process for the first set of light emitting elements (ED-1) is performed through the first transfer process, the second set of light emitting elements (ED-2) is positioned in the area between the plurality of banks (BNK) of the first set.

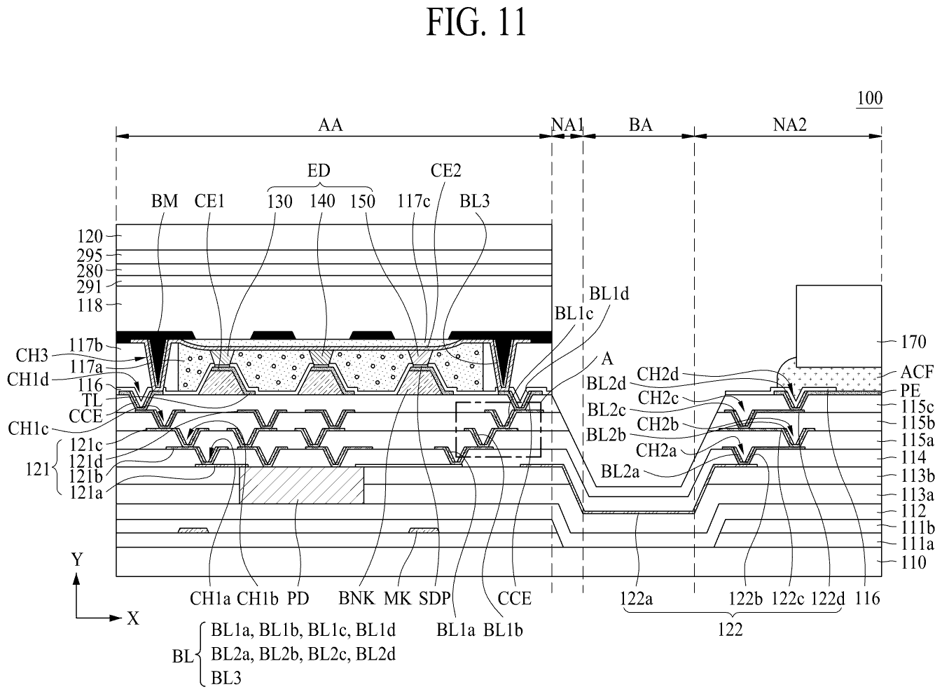

FIG. 11 is a cross-sectional view of the display panel (100) according to an example of the present disclosure.

As may be seen from FIG. 11, the display panel (100) according to another example of the present disclosure is formed by additionally including a barrier layer (BL) in a region where a contact hole is formed. By forming it in this way, it is possible to prevent the region where the contact hole is formed from being damaged by moisture or gas contained in an insulating layer provided near the region where the contact hole is formed. Furthermore, by preventing the region where the contact hole is formed from being damaged, it is possible to prevent a plurality of signal lines, connection lines, and second electrodes (CE2) provided in the region where the contact hole is formed from being damaged.

The barrier layer (BL) may include a 1-1 barrier layer (BL1a), a 1-2 barrier layer (BL1b), a 1-3 barrier layer (BL1c), a 1-4 barrier layer (BL1d), and a third barrier layer (BL3) provided in the display area (AA), and a 2-1 barrier layer (BL2a) provided in the second non-display area (NA2).

The barrier layer (BL) may be formed by including an inorganic insulating material capable of absorbing or blocking moisture or gas contained in the insulating layer or protective layer. The barrier layer (BL) may be formed by including, for example, silicon nitride (SiNx), but is not limited thereto.

The 1-1 barrier layer (BL1a) may be disposed on the third protective layer (114) and the 1-2 connection line (121b). Specifically, the 1-1 barrier layer (BL1a) may be disposed in the 1-1 contact hole (CH1a) formed in the third protective layer (114). For example, the 1-1 barrier layer (BL1a) may be disposed on an inclined surface of the 1-1 contact hole (CH1a). In the 1-1 contact hole (CH1a), a part of the 1-2 connection line (121b) may be in contact with the 1-1 connection line (121a) and the pixel driving circuit (PD) exposed by the 1-1 contact hole (CH1a), another part of the 1-2 connection line (121b) may be in contact with the inclined surface of the 1-1 contact hole (CH1a), and another part of the 1-2 connection line (121b) may be in contact with the upper surface of the third protective layer (114). The 1-1 barrier layer (BL1a) may be disposed on the 1-2 connection line (121b) in the 1-1 contact hole (CH1a). In this case, the 1-1 barrier layer (BL1a) may cover another part of the 1-2 connection line (121b) disposed on the inclined surface of the 1-1 contact hole (CH1a).

The 1-2 barrier layer (BL1b) may be disposed on the first insulating layer (115a) and the 1-3 connection line (121c). Specifically, the 1-2 barrier layer (BL1b) may be formed in the 1-2 contact hole (CH1b) disposed in the first insulating layer (115a). For example, the 1-2 barrier layer (BL1b) may be disposed on an inclined surface of the 1-2 contact hole (CH1b). In the 1-2 contact hole (CH1b), a part of the 1-3 connection line (121c) may be in contact with the 1-2 connection line (121b) exposed by the 1-2 contact hole (CH1b), another part of the 1-3 connection line (121c) may be in contact with the inclined surface of the 1-2 contact hole (CH1b), and another part of the 1-3 connection line (121c) may be in contact with the upper surface of the 2 insulating layer (115b). The 1-2 barrier layer (BL1b) may be disposed on the 1-3 connection line (121c) in the 1-2 contact hole (CH1b). In this case, the 1-2 barrier layer (BL1b) may cover another part of the 1-3 connection line (121c) disposed on the inclined surface of the 1-2 contact hole (CH1b).

The 1-3 barrier layer (BL1c) may be disposed on the second insulating layer (115b) and the 1-4 connection line (121d). Specifically, the 1-3 barrier layer (BL1c) may be formed in the 1-3 contact hole (CH1c) formed in the second insulating layer (115b). For example, the 1-3 barrier layer (BL1c) may be disposed on an inclined surface of the 1-3 contact hole (CH1c). In the 1-3 contact hole (CH1c), a part of the 1-4 connection line (121d) may be in contact with the 1-3 connection line (121c) exposed by the 1-3 contact hole (CH1c), another part of the 1-4 connection line (121d) may be in contact with the inclined surface of the 1-3 contact hole (CH1c), and another part of the 1-4 connection line (121d) may be in contact with the upper surface of the third insulating layer (115c). The 1-3 barrier layer (BL1c) may be disposed on the 1-4 connection line (121d) in the 1-3 contact hole (CH1c). In this case, the 1-3 barrier layer (BL1c) may cover another part of the 1-4 connection line (121d) disposed on the inclined surface of the 1-3 contact hole (CH1c).

The 1-4 barrier layer (BL1d) may be disposed on the third insulating layer (115c) and the contact electrode (CCE). Specifically, the 1-4 barrier layer (BL1d) may be formed in the 1-4 contact hole (CH1d) formed in the third insulating layer (115c). For example, the 1-4 barrier layer (BL1d) may be disposed on an inclined surface of the 1-4 contact hole (CH1d). A part of the contact electrode (CCE) in the 1-4 contact hole (CH1d) may be in contact with the 1-4 connection line (121d) exposed by the 1-4 contact hole (CH1d), another part of the contact electrode (CCE) may be in contact with an inclined surface of the 1-4 contact hole (CH1d), and another part of the contact electrode (CCE) may be in contact with an upper surface of the passivation layer (116). The 1-4 barrier layer (BL1d) may be disposed on the contact electrode (CCE) in the 1-4 contact hole (CH1d). In this case, the 1-4 barrier layer (BL1d) may cover another part of the contact electrode (CCE) disposed on the inclined surface of the 1-4 contact hole (CH1d).

By forming in this way, it is possible to prevent the first insulating layer (115a), the second insulating layer (115b), the third insulating layer (115c), and the passivation layer (116) from expanding in the region where the 1-1 contact hole (CH1a) to the 1-4 contact hole (CH1d) are formed due to moisture or gas contained within the first insulating layer (115a), the second insulating layer (115b), the third insulating layer (115c), and the passivation layer (116) escaping to the outside during the process of forming another insulating layer or metal layer. Accordingly, it is possible to prevent the connecting wiring formed between each insulating layer and the passivation layer from being damaged.

The 2-1 barrier layer (BL2a) may be disposed on the third protective layer (114) and the 2-2 connection line (122b). Specifically, the 2-1 barrier layer (BL2a) may be formed in the 2-1 contact hole (CH2a) formed in the third protective layer (114). For example, the 2-1 barrier layer (BL2a) may be disposed on an inclined surface of the 2-1 contact hole (CH2a). In the 2-1 contact hole (CH2a), a part of the 2-2 connection line (122b) may be in contact with the 2-1 connection line (122a) and the pixel driving circuit (PD) exposed by the 2-1 contact hole (CH2a), another part of the 2-2 connection line (122b) may be in contact with the inclined surface of the 2-1 contact hole (CH2a), and still another part of the 2-2 connection line (122b) may be in contact with the upper surface of the third protective layer (114). The 2-1 barrier layer (BL2a) may be disposed on the 2-2 connection line (122b) in the 2-1 contact hole (CH2a). In this case, the 2-1 barrier layer (BL2a) may cover another part of the 2-2 connection line (122b) disposed on the inclined surface of the 2-1 contact hole (CH2a).

The 2-2 barrier layer (BL2b) may be disposed on the first insulating layer (115a) and the 2-3 connection line (122c). Specifically, the 2-2 barrier layer (BL2b) may be formed in the 2-2 contact hole (CH2b) formed in the first insulating layer (115a). For example, the 2-2 barrier layer (BL2b) may be disposed on an inclined surface of the 2-2 contact hole (CH2b). In the 2-2 contact hole (CH2b), a part of the 2-3 connection line (122c) may be in contact with the 2-2 connection line (122b) exposed by the 2-2 contact hole (CH2b), another part of the 2-3 connection line (122c) may be in contact with the inclined surface of the 2-2 contact hole (CH2b), and another part of the 2-3 connection line (122c) may be in contact with the upper surface of the second insulating layer (115b). The 2-2 barrier layer (BL2b) may be disposed on the 2-3 connection line (122c) in the 2-2 contact hole (CH2b). In this case, the 2-2 barrier layer (BL2b) may cover another part of the 2-3 connection line (122c) disposed on the inclined surface of the 2-2 contact hole (CH2b).

The 2-3 barrier layer (BL2c) may be disposed on the second insulating layer (115b) and the 2-4 connection line (122d). Specifically, the 2-3 barrier layer (BL2c) may be formed in the 2-3 contact hole (CH2c) formed in the second insulating layer (115b). For example, the 2-3 barrier layer (BL2c) may be disposed on an inclined surface of the 2-3 contact hole (CH2c). In the 2-3 contact hole (CH2c), a part of the 2-4 connection line (122d) may be in contact with the 2-third connection line (122c) exposed by the 2-3 contact hole (CH2c), another part of the 2-4 connection line (122d) may be in contact with the inclined surface of the 2-3 contact hole (CH2c), and another part of the 2-4 connection line (122d) may be in contact with the upper surface of the third insulating layer (115c). The 2-3 barrier layer (BL2c) may be disposed on the 2-4 connection line (122d) in the 2-3 contact hole (CH2c). In this case, the 2-3 barrier layer (BL2c) may cover another part of the 2-4 connection line (122d) disposed on the inclined surface of the 2-3 contact hole (CH2c).

The 2-4 barrier layer (BL2d) may be disposed on the third insulating layer (115c) and the pad electrode (PE). Specifically, the 2-4 barrier layer (BL2d) may be formed in the 2-4 contact hole (CH2d) formed in the third insulating layer (115c). For example, the 2-4 barrier layer (BL2d) may be disposed on an inclined surface of the 2-4 contact hole (CH2d). In the 2-4 contact hole (CH2d), a part of the pad electrode (PE) may be in contact with the 2-4 connection line (122d) exposed by the 2-4 contact hole (CH2d), another part of the pad electrode (PE) may be in contact with the inclined surface of the 2-4 contact hole (CH2d), and another part of the pad electrode (PE) may be in contact with the upper surface of the passivation layer (116). The 2-4 barrier layer (BL2d) may be disposed on the pad electrode (PE) in the 2-4 contact hole (CH2d). In this case, the 2-4 barrier layer (BL2d) may cover another part of the pad electrode (PE) disposed on the inclined surface of the 2-4 contact hole (CH2d).

By forming in this way, it is possible to prevent the first insulating layer (115a), the second insulating layer (115b), the third insulating layer (115c), and the passivation layer (116) from expanding in the region where the 2-1 contact hole (CH2a) to the 2-4 contact hole (CH2d) are formed due to moisture or gas contained within the first insulating layer (115a), the second insulating layer (115b), the third insulating layer (115c), and the passivation layer (116) escaping to the outside during the process of forming another insulating layer or metal layer. Accordingly, it is possible to prevent the connection line formed between each insulating layer and the passivation layer from being damaged.

The third barrier layer (BL3) may be disposed on the second optical layer (117b) and the second electrode (CE2). Specifically, the third barrier layer (BL3) may be formed in the third contact hole (CH3) formed in the second optical layer (117b). For example, the third barrier layer (BL3) may be disposed on an inclined surface of the third contact hole (CH3). In the third contact hole (CH3), a part of the second electrode (CE2) may be in contact with the contact electrode (CCE) exposed by the third contact hole (CH3), another part of the second electrode (CE2) may be in contact with the inclined surface of the third contact hole (CH3), and another part of the second electrode (CE2) may be in contact with the upper surface of the black matrix (BM). The third barrier layer (BL3) may be disposed on the second electrode (CE2) in the third contact hole (CH3). In this case, the third barrier layer (BL3) may cover another part of the second electrode (CE2) disposed on the inclined surface of the third contact hole (CH3).

By forming in this way, it is possible to prevent the black matrix (BM) from expanding in the area where the third contact hole (CH3) is formed as moisture or gas contained within the black matrix (BM) escapes to the outside during the process of forming another insulating layer or metal layer. Accordingly, it is possible to prevent the second electrode (CE2) formed between the second optical layer (117b) and the black matrix (BM) from being damaged.

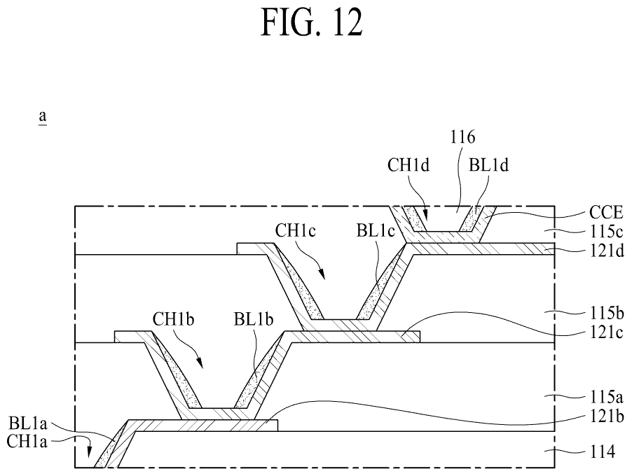

FIG. 12 is a cross-sectional view of the display panel (100) according to an example of the present disclosure, and is an enlarged view of area A of FIG. 11. In this case, FIG. 12 mainly describes the 1-3 connection line (121c), the 1-4 connection line (121d), the 1-2 barrier layer (BL1b), and the 1-3 barrier layer (BL1c), but the same may be applied to other wires on which the barrier layer (BL) is formed, for example, the 1-2 connection line (121b) to the 1-4 connection line (121d), the 2-2 connection line (122b) to the 2-4 connection line (122d), the contact electrode (CCE), the pad electrode (PE), and the second electrode (CE2).

As may be seen in FIG. 12, the 1-3 connection line (121c) may be electrically connected to the 1-2 connection line (121b) through the 1-2 contact hole (CH1b) formed in the first insulating layer (115a).

According to an example of the present disclosure, a barrier layer (BL) may be disposed on a connection line and/or an electrode at an inclined surface of a plurality of contact holes. For example, a 1-2 barrier layer (BL1b) may be formed in a 1-2 contact hole (CH1b), and the 1-2 barrier layer (BL1b) may be provided to cover an inclined surface of the 1-2 contact hole (CH1b). In this case, the 1-2 barrier layer (BL1b) may be provided to cover a part of a 1-3 connection line (121c) formed in the 1-2 contact hole (CH1b).

The 1-2 barrier layer (BL1b) may not be disposed on the upper surface of the first insulating layer (115a), specifically, on the upper surface of the first insulating layer (115a) where the 1-2 contact hole (CH1b) is not formed. The 1-2 barrier layer (BL1b) may not overlap the upper surface of the first insulating layer (115a).

The lower surface of the 1-2 barrier layer (BL1b) is in contact with a portion of the 1-3 connection line (121c) that is in contact with the 1-2 connection line (121b), and within the 1-2 contact hole (CH1b), the 1-2 barrier layer (BL1b) may expose a portion of the upper surface of the 1-3 connection line (121c) to the outside.

The 1-2 barrier layer (BL1b) may include a first surface that is in contact with the 1-3 connection line (121c) and a second surface that faces the first surface. The first surface and the second surface may be provided with different shapes. Specifically, the first surface that is in contact with the 1-3 connection line (121c) may be disposed along the shape of the 1-3 connection line (121c). In this case, since the 1-3 connection line (121c) is disposed along the inclined surface of the 1-2 contact hole (CH1b), the first surface may be disposed along the inclined surface of the 1-2 contact hole (CH1b).

The second surface of the 1-2 barrier layer (BL1b) may be provided to have a convex shape from the inclined surface of the 1-2 contact hole (CH1b). The 1-2 barrier layer (BL1b) may be formed, for example, through a deposition and etching process. In this case, when a material for forming the 1-2 barrier layer (BL1b) is entirely deposited on the inside of the 1-2 contact hole (CH1b) and the outside of the 1-2 contact hole (CH1b), the material for forming the 1-2 barrier layer (BL1b) may be formed to have a convex surface in an area overlapping with the inclined surface of the 1-2 contact hole (CH1b). Furthermore, when an etching process is performed on the material used to form the 1-2 barrier layer (BL1b) such that the top surface of the 1-3 connection line (121c) is exposed, the 1-2 barrier layer (BL1b), which is disposed on the inclined surface of the 1-2 contact hole (CH1b), may have a convex surface with respect to the inclined surface, rather than a flat surface. However, it is not limited thereto.

For example, a 1-3 barrier layer (BL1c) may be formed in a 1-3 contact hole (CH1c), and the 1-3 barrier layer (BL1c) may be provided to cover an inclined surface of the 1-3 contact hole (CH1c). In this case, the 1-3 barrier layer (BL1c) may be provided on an upper portion of a 1-4 connection line (121d) formed in the 1-3 contact hole (CH1c). Meanwhile, the description of the 1-3 contact hole (CH1c) and the 1-3 barrier layer (BL1c) is the same as the description of the 1-2 contact hole (CH1b) and the 1-2 barrier layer (BL1b), and therefore, repeated descriptions will be omitted.

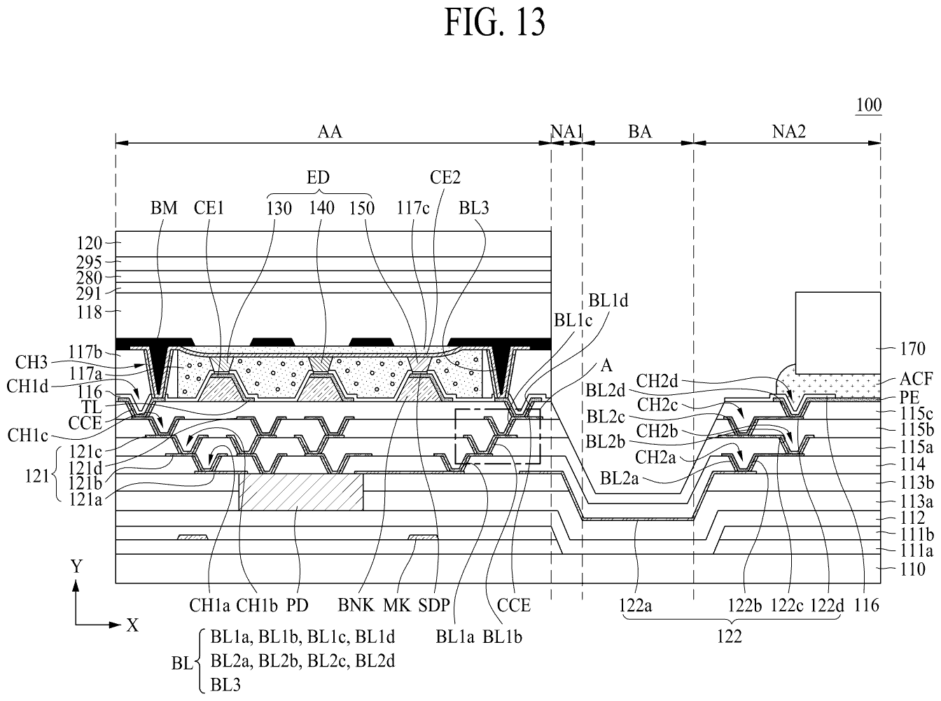

FIG. 13 is a cross-sectional view of the display panel (100) according to an example of the present disclosure. Meanwhile, the example of FIG. 13 is identical to the example of FIG. 12 except for the position of the barrier layer (BL), so the following description will focus on the different configuration.

According to an example of the present disclosure, a barrier layer (BL) may be placed under each of the connection lines (121, 122), the contact electrode (CCE), the pad electrode (PE), and the second electrode (CE2) provided in an area where a contact hole is formed.

The 1-1 barrier layer (BL1a) may be disposed on the third protective layer (114) and the 1-2 connection line (121b). Specifically, the 1-1 barrier layer (BL1a) may be formed in the 1-1 contact hole (CH1a) formed in the third protective layer (114). The 1-1 barrier layer (BL1a) may be disposed under the 1-2 connection line (121b) in the 1-1 contact hole (CH1a). In this case, the 1-1 barrier layer (BL1a) may cover the inclined surface of the 1-1 contact hole (CH1a), and the 1-2 connection line (121b) may be disposed on the inclined surface of the 1-1 contact hole (CH1a) along the shape of the 1-1 barrier layer (BL1a).

The 1-2 barrier layer (BL1b) may be disposed on the first insulating layer (115a) and the 1-3 connection line (121c). Specifically, the 1-2 barrier layer (BL1b) may be formed in the 1-2 contact hole (CH1b) formed in the first insulating layer (115a). The 1-2 barrier layer (BL1b) may be disposed under the 1-3 connection line (121c) in the 1-2 contact hole (CH1b). In this case, the 1-1 barrier layer (BL1a) may cover the inclined surface of the 1-1 contact hole (CH1a), and the 1-2 connection line (121b) may be disposed on the inclined surface of the 1-1 contact hole (CH1a) along the shape of the 1-1 barrier layer (BL1a).

The 1-3 barrier layer (BL1c) may be disposed on the second insulating layer (115b) and the 1-4 connection line (121d). Specifically, the 1-3 barrier layer (BL1c) may be formed in the 1-3 contact hole (CH1c) formed in the second insulating layer (115b). The 1-3 barrier layer (BL1c) may be disposed under the 1-4 connection line (121d) in the 1-3 contact hole (CH1c). In this case, the 1-1 barrier layer (BL1a) may cover the inclined surface of the 1-1 contact hole (CH1a), and the 1-second connection line (121b) may be disposed on the inclined surface of the 1-1 contact hole (CH1a) along the shape of the 1-1 barrier layer (BL1a).

The 1-4 barrier layer (BL1d) may be disposed on the third insulating layer (115c) and the contact electrode (CCE). Specifically, the 1-4 barrier layer (BL1d) may be formed in the 1-4 contact hole (CH1d) formed in the third insulating layer (115c). The 1-4 barrier layer (BL1d) may be disposed under the contact electrode (CCE) in the 1-4 contact hole (CH1d). In this case, the 1-1 barrier layer (BL1a) may cover the inclined surface of the 1-1 contact hole (CH1a), and the 1-2 connection line (121b) may be disposed on the inclined surface of the 1-1 contact hole (CH1a) along the shape of the 1-1 barrier layer (BL1a).

By forming in this way, it is possible to prevent the first insulating layer (115a), the second insulating layer (115b), the third insulating layer (115c), and the passivation layer (116) from expanding in the region where the 1-1 contact hole (CH1a) to the 1-4 contact hole (CH1d) are formed due to moisture or gas contained within the first insulating layer (115a), the second insulating layer (115b), the third insulating layer (115c), and the passivation layer (116) escaping to the outside during the process of forming another insulating layer or metal layer. Accordingly, it is possible to prevent the connection line formed between each insulating layer and the passivation layer from being damaged.

The 2-1 barrier layer (BL2a) may be disposed on the third protective layer (114) and the 2-2 connection line (122b). Specifically, the 2-1 barrier layer (BL2a) may be formed in the 2-1st contact hole (CH2a) formed in the third protective layer (114). The 2-1 barrier layer (BL2a) may be disposed under the 2-2 connection line (122b) in the 2-1st contact hole (CH2a). In this case, the 1-1 barrier layer (BL1a) may cover the inclined surface of the 1-1 contact hole (CH1a), and the 1-second connection line (121b) may be disposed on the inclined surface of the 1-1 contact hole (CH1a) along the shape of the 1-1 barrier layer (BL1a).

The 2-2 barrier layer (BL2b) may be disposed on the first insulating layer (115a) and the 2-3 connection line (122c). Specifically, the 2-2 barrier layer (BL2b) may be formed in the 2-2 contact hole (CH2b) formed in the first insulating layer (115a). The 2-2 barrier layer (BL2b) may be disposed under the 2-3 connection line (122c) in the 2-2 contact hole (CH2b). In this case, the 1-1 barrier layer (BL1a) may cover the inclined surface of the 1-1 contact hole (CH1a), and the 1-2 connection line (121b) may be disposed on the inclined surface of the 1-1 contact hole (CH1a) along the shape of the 1-1 barrier layer (BL1a).

The 2-3 barrier layer (BL2c) may be disposed on the second insulating layer (115b) and the 2-4 connection line (122d). Specifically, the 2-3 barrier layer (BL2c) may be formed in the 2-3 contact hole (CH2c) formed in the second insulating layer (115b). The 2-3 barrier layer (BL2c) may be disposed under the 2-4 connection line (122d) in the 2-3 contact hole (CH2c). In this case, the 1-1 barrier layer (BL1a) may cover the inclined surface of the 1-1 contact hole (CH1a), and the 1-second connection line (121b) may be disposed on the inclined surface of the 1-1 contact hole (CH1a) along the shape of the 1-1 barrier layer (BL1a).

The 2-4 barrier layer (BL2d) may be disposed on the third insulating layer (115c) and the pad electrode (PE). Specifically, the 2-4 barrier layer (BL2d) may be formed in the 2-4 contact hole (CH2d) formed in the third insulating layer (115c). The 2-4 barrier layer (BL2d) may be disposed under the pad electrode (PE) in the 2-4 contact hole (CH2d). In this case, the 1-1 barrier layer (BL1a) may cover the inclined surface of the 1-1 contact hole (CH1a), and the 1-2 connection line (121b) may be disposed on the inclined surface of the 1-1 contact hole (CH1a) along the shape of the 1-1 barrier layer (BL1a).

By forming in this way, it is possible to prevent the first insulating layer (115a), the second insulating layer (115b), the third insulating layer (115c), and the passivation layer (116) from expanding in the region where the 2-1 contact hole (CH2a) to the 2-4 contact hole (CH2d) are formed due to moisture or gas contained within the first insulating layer (115a), the second insulating layer (115b), the third insulating layer (115c), and the passivation layer (116) escaping to the outside during the process of forming another insulating layer or metal layer. Accordingly, it is possible to prevent the connection line disposed between each insulating layer and the passivation layer from being damaged.

The third barrier layer (BL3) may be disposed on the second optical layer (117b) and the second electrode (CE2). Specifically, the third barrier layer (BL3) may be formed in the third contact hole (CH3) formed in the second optical layer (117b). The third barrier layer (BL3) may be disposed under the second electrode (CE2) in the third contact hole (CH3). In this case, the 1-1 barrier layer (BL1a) may cover the inclined surface of the 1-1 contact hole (CH1a), and the 1-2 connection line (121b) may be disposed on the inclined surface of the 1-1 contact hole (CH1a) along the shape of the 1-1 barrier layer (BL1a).

By forming in this way, it is possible to prevent the black matrix (BM) from expanding in the area where the third contact hole (CH3) is formed as moisture or gas contained within the black matrix (BM) escapes to the outside during the process of forming another insulating layer or metal layer. Accordingly, it is possible to prevent the second electrode (CE2) disposed between the second optical layer (117b) and the black matrix (BM) from being damaged.

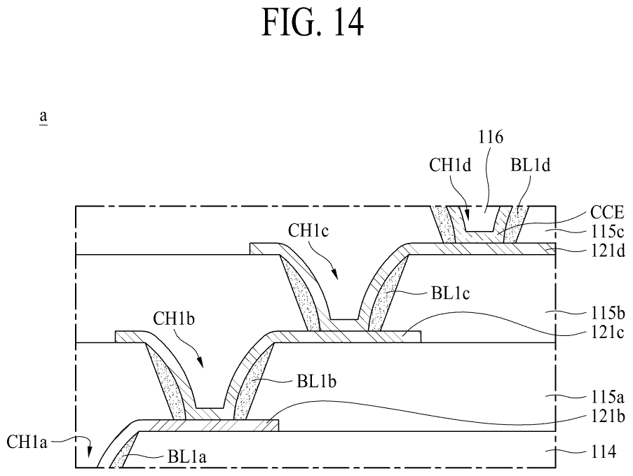

FIG. 14 is a cross-sectional view of the display panel (100) according to an example of the present disclosure, and is an enlarged view of area A of FIG. 13. In this case, FIG. 14 mainly describes the 1-3 connection line (121c), the 1-4 connection line (121d), the 1-2 barrier layer (BL1b), and the 1-3 barrier layer (BL1c), but the same may be applied to other wires on which the barrier layer (BL) is formed, for example, the 1-2 connection line (121b) to the 1-4 connection line (121d), the 2-2 connection line (122b) to the 2-4 connection line (122d), the contact electrode (CCE), the pad electrode (PE), and the second electrode (CE2).

As may be seen in FIG. 14, the 1-3 connection line (121c) may be electrically connected to the 1-2 connection line (121b) through the 1-2 contact hole (CH1b) formed in the first insulating layer (115a).

According to an example of the present disclosure, a barrier layer (BL) may be disposed under a connection line and/or an electrode on an inclined surface of a plurality of contact holes. For example, a 1-2 barrier layer (BL1b) may be formed in a 1-2 contact hole (CH1b), and the 1-2 barrier layer (BL1b) may be provided to cover an inclined surface of the 1-2 contact hole (CH1b). In this case, a 1-3 connection line (121c) may be disposed on the 1-2 barrier layer (BL1b) formed in the 1-2 contact hole (CH1b).

The 1-2 barrier layer (BL1b) may not be disposed on the upper surface of the first insulating layer (115a), specifically, on the upper surface of the first insulating layer (115a) where the 1-2 contact hole (CH1b) is not formed. The 1-2 barrier layer (BL1b) may not overlap the upper surface of the first insulating layer (115a).

The lower surface of the 1-2 barrier layer (BL1b) is in contact with the 1-2 connection line (121b), and the 1-2 barrier layer (BL1b) may expose a part of the upper surface of the 1-2 connection line (121b) to the outside within the 1-2 contact hole (CH1b). Specifically, the 1-2 barrier layer (BL1b) exposes the 1-2 connection line (121b) provided on the upper surface of the third protective layer (114) to the outside, and the upper surface of the 1-2 connection line (121b) exposed to the outside and the 1-3 connection line (121c) may be electrically connected to each other.

The 1-2 barrier layer (BL1b) may include a first surface that is in contact with the inclined surface of the 1-2 contact hole (CH1b) and a second surface that faces the first surface. The first surface and the second surface may have different shapes. Specifically, the first surface that is in contact with the inclined surface of the 1-2 contact hole (CH1b) may be disposed along the shape of the inclined surface of the 1-2 contact hole (CH1b).

The second surface of the 1-2 barrier layer (BL1b) may be provided to have a convex shape from the inclined surface of the 1-2 contact hole (CH1b). The 1-2 barrier layer (BL1b) may be formed, for example, through a deposition and etching process. In this case, when a material for forming the 1-2 barrier layer (BL1b) is entirely deposited on the inside of the 1-2 contact hole (CH1b) and the outside of the 1-2 contact hole (CH1b), the material for forming the 1-2 barrier layer (BL1b) may be formed to have a convex surface in an area overlapping with the inclined surface of the 1-2 contact hole (CH1b). Furthermore, when an etching process is performed on the material used to form the 1-2 barrier layer (BL1b) so that the top surface of the 1-3 connection line (121c) is exposed, the 1-2 barrier layer (BL1b) disposed on the inclined surface of the 1-2 contact hole (CH1b) may have a convex surface relative to the inclined surface of the contact hole, rather than a flat surface. However, it is not limited thereto.

According to an example of the present disclosure, the 1-3 connection line (121c) formed in the 1-2 contact hole (CH1b) is disposed on the 1-2 barrier layer (BL1b), and thus may have a convex surface following the shape of the convex second surface of the 1-2 barrier layer (BL1b).

For example, a 1-3 barrier layer (BL1c) may be formed in a 1-3 contact hole (CH1c), and the 1-3 barrier layer (BL1c) may be provided to cover an inclined surface of the 1-3 contact hole (CH1c). In this case, the 1-3 barrier layer (BL1c) may be formed below a 1-4 connection line (121d) formed in the 1-3 contact hole (CH1c). Meanwhile, the description of the 1-3 contact hole (CH1c) and the 1-3 barrier layer (BL1c) is the same as the description of the 1-2 contact hole (CH1b) and the 1-2 barrier layer (BL1b), and therefore, repeated descriptions will be omitted.

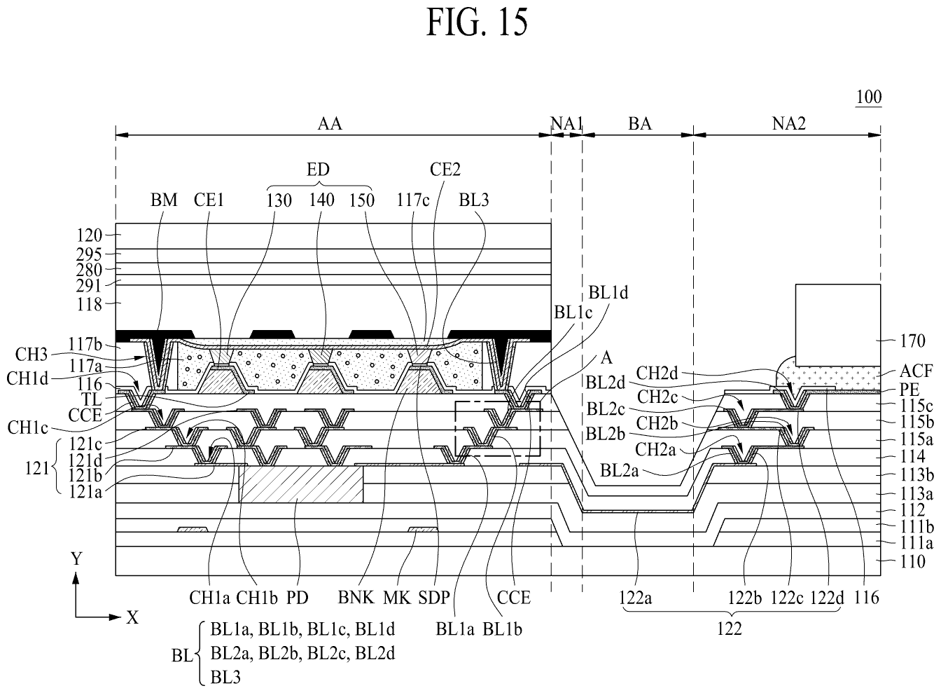

FIG. 15 is a cross-sectional view of the display panel (100) according to an example of the present disclosure. Meanwhile, the example of FIG. 15 is identical to the example of FIG. 12 except for the position of the barrier layer (BL), so the following description will focus on the different configuration.

According to an example of the present disclosure, the barrier layer (BL) may be disposed above and below each of the connection lines (121, 122), the contact electrode (CCE), the pad electrode (PE), and the second electrode (CE2) provided in the area where the contact hole is formed.

For example, the 1-1 barrier layer (BL1a) may be disposed on an inclined surface of the 1-1 contact hole (CH1a). Specifically, the 1-1 barrier layer (BL1a) may be disposed between the third protective layer (114) and the 1-2 connection line (121b) on an inclined surface of the 1-1 contact hole (CH1a), and at the same time, may be disposed between the 1-2 connection line (121b) and the first insulating layer (115a).

For example, the 1-2 barrier layer (BL1b) may be disposed on an inclined surface of the 1-2 contact hole (CH1b). Specifically, the 1-2 barrier layer (BL1b) may be disposed between the first insulating layer (115a) and the 1-3 connection line (121c) on an inclined surface of the 1-2 contact hole (CH1b), and at the same time, may be disposed between the 1-3 connection line (121c) and the second insulating layer (115b).

For example, the 1-3 barrier layer (BL1c) may be disposed on an inclined surface of the 1-3 contact hole (CH1c). Specifically, the 1-3 barrier layer (BL1c) may be disposed between the second insulating layer (115b) and the 1-4 connection line (121d) on an inclined surface of the 1-3 contact hole (CH1c), and at the same time, may be disposed between the 1-4 connection line (121d) and the third insulating layer (115c).

For example, the 1-4 barrier layer (BL1d) may be disposed on an inclined surface of the 1-4 contact hole (CH1d). Specifically, the 1-4 barrier layer (BL1d) may be disposed between the third insulating layer (115c) and the contact electrode (CCE) on an inclined surface of the 1-4 contact hole (CH1d), and at the same time, may be disposed between the contact electrode (CCE) and the passivation layer (116).

By being formed in this manner, it is possible to prevent the third protective layer (114), the insulating layer (115a to 115c) or the passivation layer (116) from being damaged by expansion in the area where the contact hole is formed due to moisture or gas contained within the third protective layer (114), the insulating layer (115a to 115c) or the passivation layer (116) disposed above and below the connection line (121) and the contact electrode (CCE), and further, it is possible to prevent damage to the connection line (121) and the contact electrode (CCE).

For example, the 2-1 barrier layer (BL2a) may be disposed on an inclined surface of the 2-1 contact hole (CH2a). Specifically, the 2-1 barrier layer (BL2a) may be disposed between the third protective layer (114) and the 2-2 connection line (122b) on an inclined surface of the 2-1 contact hole (CH2a), and at the same time, may be disposed between the 2-2 connection line (122b) and the first insulating layer (115a).

For example, the 2-2 barrier layer (BL2b) may be disposed on an inclined surface of the 2-2 contact hole (CH2b). Specifically, the 2-2 barrier layer (BL2b) may be disposed between the first insulating layer (115a) and the 2-3 connection line (122c) on an inclined surface of the 2-2 contact hole (CH2b), and at the same time, may be disposed between the 2-3 connection line (122c) and the second insulating layer (115b).

For example, the 2-3 barrier layer (BL2c) may be disposed on an inclined surface of the 2-3 contact hole (CH2c). Specifically, the 2-3 barrier layer (BL2c) may be disposed between the second insulating layer (115b) and the 2-4 connection line (122d) on an inclined surface of the 2-3 contact hole (CH2c), and at the same time, may be disposed between the 2-4 connection line (122d) and the third insulating layer (115c).

For example, the 2-4 barrier layer (BL2d) may be disposed on an inclined surface of the 2-4 contact hole (CH2d). Specifically, the 2-4 barrier layer (BL2d) may be disposed between the third insulating layer (115c) and the pad electrode (PE) on the inclined surface of the 2-4 contact hole (CH2d), and at the same time, may be disposed between the pad electrode (PE) and the passivation layer (116).

By forming in this way, it is possible to prevent the third protective layer (114), the insulating layer (115a to 115c) or the passivation layer (116) from being damaged by expansion in the area where the contact hole is formed due to moisture or gas contained within the third protective layer (114), the insulating layer (115a to 115c) or the passivation layer (116) disposed above and below the connection line (122) and the pad electrode (PE), and further prevent damage to the connection line (122) and the pad electrode (PE).

For example, the third barrier layer (BL3) may be disposed on an inclined surface of the third contact hole (CH3). Specifically, the third barrier layer (BL3) may be disposed between the second optical layer (117b) and the second electrode (CE2) on the inclined surface of the third contact hole (CH3), and at the same time, may be disposed between the second electrode (CE2) and the black matrix (BM).

By forming in this way, it is possible to prevent the second optical layer (117b) or the black matrix (BM) from being damaged by expansion in the area where the contact hole is formed due to moisture or gas contained within the second optical layer (117b) and the black matrix (BM) disposed above and below the second electrode (CE2), and further, to prevent damage to the second electrode (CE2).

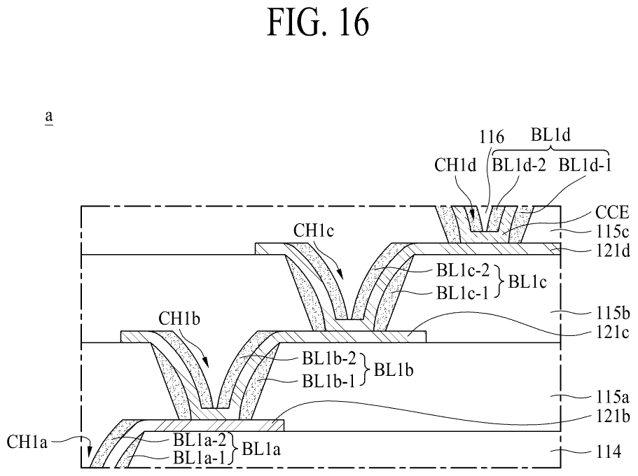

FIG. 16 is a cross-sectional view of the display panel (100) according to an example of the present disclosure, and is an enlarged view of area A of FIG. 15. In this case, FIG. 16 mainly describes the 1-3 connection line (121c), the 1-4 connection line (121d), the 1-2 barrier layer (BL1b), and the 1-3 barrier layer (BL1c), but the same may be applied to other wires on which a barrier layer (BL) is formed, for example, the 1-2 connection line (121b) to the 1-4 connection line (121d), the 2-2 connection line (122b) to the 2-4 connection line (122d), the contact electrode (CCE), the pad electrode (PE), and the second electrode (CE2).

As may be seen in FIG. 16, the 1-3 connection line (121c) may be electrically connected to the 1-2 connection line (121b) through the 1-2 contact hole (CH1b) formed in the first insulating layer (115a).

According to an example of the present disclosure, the barrier layer (BL) may be disposed on both the upper and lower sides of the connection line and/or electrode at the inclined surfaces of the plurality of contact holes. For example, the 1-2 barrier layer (BL1b) may be formed in the 1-2 contact hole (CH1b). The 1-2 barrier layer (BL1b) may not be disposed on the upper surface of the first insulating layer (115a), specifically, on the upper surface of the first insulating layer (115a) where the 1-2 contact hole (CH1b) is not formed. The 1-2 barrier layer (BL1b) may not overlap the upper surface of the first insulating layer (115a).

Specifically, the 1-2 barrier layer (BL1b) includes a lower 1-2 barrier layer (BL1b-1) and an upper 1-2 barrier layer (BL1b-2).

The lower 1-2 barrier layer (BL1b-1) may be provided to cover the inclined surface of the 1-2 contact hole (CH1b). In this case, the 1-3 connection line (121c) may be disposed on the lower 1-2 barrier layer (BL1b-1) formed in the 1-2 contact hole (CH1b).

The lower surface of the lower 1-2 barrier layer (BL1b-1) is in contact with the 1-2 connection line (121b), and the lower 1-2 barrier layer (BL1b-1) may expose a part of the upper surface of the 1-2 connection line (121b) to the outside within the 1-2 contact hole (CH1b). Accordingly, the upper surface of the 1-2 connection line (121b) exposed to the outside and the 1-3 connection line (121c) may be electrically connected to each other.

The lower 1-2 barrier layer (BL1b-1) may include a first surface that is in contact with the inclined surface of the 1-2 contact hole (CH1b) and a second surface that faces the first surface. The first surface and the second surface may have different shapes. Specifically, the first surface that is in contact with the inclined surface of the 1-2 contact hole (CH1b) may be disposed along the shape of the inclined surface of the 1-2 contact hole (CH1b).

The second surface of the lower 1-2 barrier layer (BL1b-1) may be provided to have a convex shape from the inclined surface of the 1-2 contact hole (CH1b).

According to the example of the present disclosure, since the 1-3 connection line (121c) formed in the 1-2 contact hole (CH1b) is disposed on the lower 1-2 barrier layer (BL1b-1), it may have a convex surface following the shape of the convex second surface of the lower 1-2 barrier layer (BL1b-1).

The upper 1-2 barrier layer (BL1b-2) may be provided to cover the inclined surface of the 1-2 contact hole (CH1b). In this case, the upper 1-2 barrier layer (BL1b-2) may be provided to cover a portion of the 1-3 connection line (121c) formed in the 1-2 contact hole (CH1b).

The lower surface of the upper 1-2 barrier layer (BL1b-2) is in contact with a portion of the 1-3 connection line (121c) that is in contact with the 1-2 connection line (121b), and within the 1-2 contact hole (CH1b), the upper 1-2 barrier layer (BL1b-2) may expose a portion of the upper surface of the 1-3 connection line (121c) to the outside.

The upper 1-2 barrier layer (BL1b-2) may include a first surface that is in contact with the 1-3 connection line (121c) and a second surface that faces the first surface. According to an example of the present disclosure, the first surface and the second surface may have the same shape. Specifically, the first surface and the second surface that are in contact with the 1-3 connection line (121c) may be disposed along the shape of the 1-3 connection line (121c). Accordingly, the first surface and the second surface of the upper 1-2 barrier layer (BL1b-2) may be provided to have a convex shape from the inclined surface of the 1-2 contact hole (CH1b). However, the present disclosure is not limited thereto.

For example, a 1-3 barrier layer (BL1c) may be formed in a 1-3 contact hole (CH1c), and the 1-3 barrier layer (BL1c) may be provided to cover an inclined surface of the 1-3 contact hole (CH1c). In this case, the 1-3 barrier layer (BL1c) may be disposed on the upper and lower portions of the 1-4 connection line (121d) formed in the 1-3 contact hole (CH1c). Meanwhile, the description of the 1-3 contact hole (CH1c) and the 1-3 barrier layer (BL1c) is the same as the description of the 1-2 contact hole (CH1b) and the 1-2 barrier layer (BL1b), and therefore, repeated descriptions will be omitted.

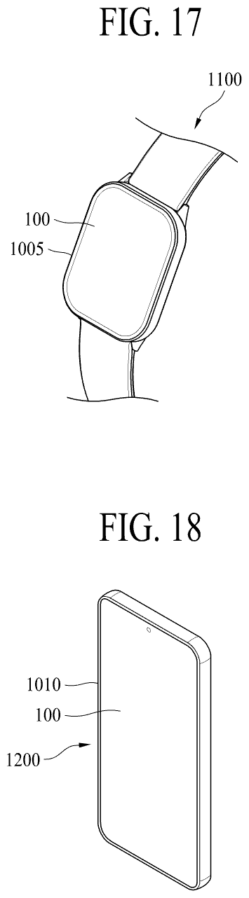

FIGS. 17 to 20 are drawings showing devices to which display devices according to examples of the present disclosure are applied.

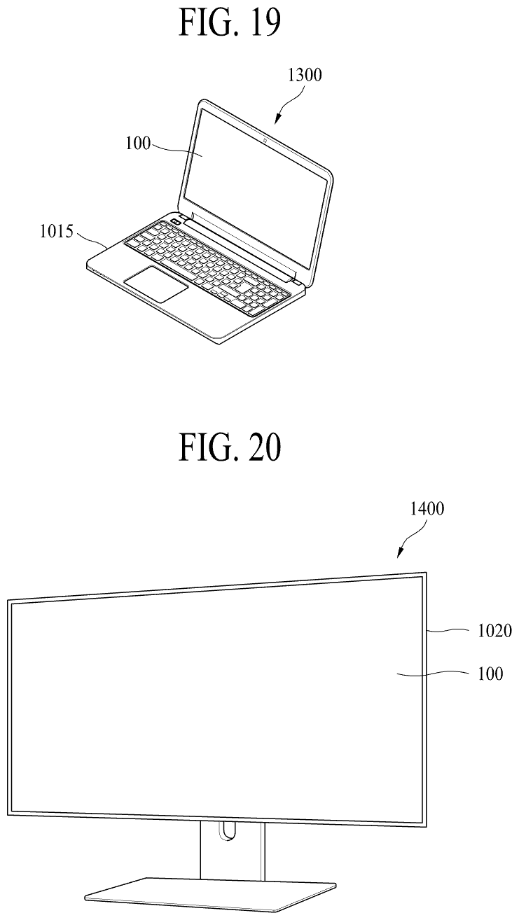

Referring to FIGS. 17 to 20, the display device (1000) according to the examples of the present disclosure may be included in various devices or electronic devices. For example, the various electronic devices may include a wearable device (1100) as in FIG. 17, a mobile device (1200) as in FIG. 18, a notebook (1Q) as in FIG. 19, and a monitor or TV (1400) as in FIG. 20, but the examples of the present disclosure are not limited thereto.

Each of the wearable device (1100), the mobile device (1200), the notebook (1300), and the monitor or TV (1400) may include a case (1005, 1010, 1015, 1020) and a display panel (100) and a display device (1000) other than those of the examples of the present disclosure described above.

For example, the display device (1000) according to an example of the present disclosure may be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an electronic book, a portable multimedia player (PMP), a personal digital assistant (PDA), an MP3 player, a mobile medical device, a desktop PC, a laptop PC, a netbook computer, a workstation, a navigation system, a vehicle display device, a theater display device, a television, a wallpaper device, a signage device, a game device, a notebook, a monitor, a camera, a camcorder, and home appliances.

Although the examples of the present disclosure have been described in more detail with reference to the attached drawings, the present disclosure is not necessarily limited to these examples, and various modifications may be made without departing from the technical spirit of the present disclosure. Accordingly, the examples disclosed in the present disclosure are not intended to limit the technical spirit of the present disclosure, but to explain, and the scope of the technical spirit of the present disclosure is not limited by these examples. Therefore, the examples described above should be understood as illustrative and not restrictive in all respects.

According to the present disclosure, by forming a barrier layer capable of absorbing and/or blocking moisture or gas in a plurality of contact hole regions formed to connect a plurality of wires disposed between a plurality of insulating layers, damage to the region where the contact holes are formed may be suppressed or eliminated.

According to the present disclosure, by forming a barrier layer in a contact hole region formed in an optical layer to connect a second electrode and a contact electrode, damage to the region where the contact hole is formed may be suppressed or eliminated.

According to the present disclosure, by forming a barrier layer in an area where a contact hole is formed, damage to a plurality of connection lines, connecting electrodes, and second electrodes may be suppressed or eliminated.

According to the present disclosure, instead of forming a plurality of transistors and storage capacitors in each of a plurality of subpixels, a pixel driving circuit in which a plurality of pixel circuits is integrated may be used to simplify the structure of a display device, and high-efficiency, low-power driving is possible.

According to this disclosure, a main light emitting element and a redundant light emitting element are transferred together to each subpixel, so that when the main light emitting element is defective, the redundant light emitting element may be used as a replacement, thereby reducing the deterioration of display quality due to defective transfer of the light emitting element.

The aspects of this disclosure are not limited to the aspects mentioned above, and other aspects not mentioned will be clearly understood by those of ordinary skill in the art from the description of the claims.

What is claimed is:

1. A display device, comprising:
a substrate including a display area and a non-display area;
a pixel driving circuit disposed in the display area on the substrate;
a bank disposed on the pixel driving circuit;
a light emitting element disposed on the bank;
an optical layer covering side surfaces of the bank and side surfaces of the light emitting element;
a black matrix disposed on the optical layer; and
a first barrier layer disposed on an inclined surface of a first contact hole in the optical layer.

2. The display device of claim 1, further comprising:
a second electrode disposed between the optical layer and the black matrix and connected to the light emitting element, wherein the second electrode is in contact with the first barrier layer in the first contact hole.

3. The display device of claim 2, wherein the first barrier layer is disposed on the second electrode and below the black matrix.

4. The display device of claim 3, wherein the first barrier layer comprises:
a first surface adjacent to the optical layer, and
a second surface adjacent to the black matrix, wherein the second surface is convex in shape from the inclined surface.

5. The display device of claim 2, wherein the first barrier layer is disposed below the second electrode and on the optical layer.

6. The display device of claim 5, wherein the first barrier layer comprises:
a first surface adjacent to the optical layer, and
a second surface adjacent to the black matrix, wherein the first surface is convex in shape from the inclined surface.

7. The display device of claim 6, wherein the second electrode is disposed along the first surface of the first barrier layer in a convex shape from the inclined surface of the first contact hole.

8. The display device of claim 2, wherein the first barrier layer comprises:
an upper first barrier layer disposed on the second electrode and below the black matrix; and
a lower first barrier layer disposed below the second electrode and on the optical layer.

9. The display device of claim 8, wherein the lower first barrier layer comprises:
a third surface adjacent to the optical layer, and
a fourth surface adjacent to the black matrix, wherein the fourth surface is convex in shape from the inclined surface.

10. The display device of claim 9, wherein the second electrode and the top first barrier layer are disposed along the fourth surface of the bottom first barrier layer in a convex shape from the inclined surface of the first contact hole.

11. The display device of claim 1, wherein the first barrier layer does not overlap with an upper surface of the optical layer.

12. The display device of claim 1, wherein the first barrier layer includes an inorganic insulating material.

13. The display device of claim 1, wherein the optical layer comprises:
a first optical layer contacting the side surfaces of the bank and the side surfaces of the light emitting element; and
a second optical layer disposed at a side of the first optical layer and having the first contact hole.

14. The display device of claim 1, further comprising:
an insulating layer disposed between the pixel driving circuit and the bank, wherein the insulating layer comprises:
a first insulating layer disposed on the pixel driving circuit and having a second contact hole; and
a second insulating layer disposed on the first insulating layer and below the bank; and
a second barrier layer disposed on an inclined surface of the second contact hole of the first insulating layer.

15. The display device of claim 14, wherein the second barrier layer includes an inorganic insulating material.

16. The display device of claim 14, further comprising:
a connection line disposed between the first and second insulating layers, wherein the connection line is disposed in the second contact hole and contacts the second barrier layer.

17. The display device of claim 16, wherein the second barrier layer is disposed on the connection line and below the second insulating layer.

18. The display device of claim 16, wherein the second barrier layer is disposed below the connection line and on the first insulating layer.

19. The display device of claim 16, wherein the second barrier layer comprises:
a top second barrier layer disposed on the connection line and below the second insulating layer; and
a bottom second barrier layer disposed below the connection line and on the first insulating layer.

20. The display device of claim 14, wherein the second barrier layer does not overlap with an upper surface of the first insulating layer.
